(19) United States
(12) Patent Application Publication
(10) Pub. No.: US 2018/0336139 A1
(43) Pub. Date: Nov. 22, 2018

(54) SYSTEMS AND METHODS FOR A HIGHLY-AVAILABLE MEMORY

(71) Applicant: SanDisk Technologies LLC, Plano, TX (US)

(72) Inventors: Lakkimsetty Venkateswara Rao, Bangalore (IN); HimaBindu V, Bangalore (IN)

(21) Appl. No.: 15/596,355

(22) Filed: May 16, 2017

(51) Int. Cl. G06F 12/0871; G06F 3/06; G06F 11/10; G11C 16/10

(52) U.S. Cl. CPC G06F 12/0871; G06F 3/0617; G11C 2216/14; G11C 16/105; G06F 11/1052

(57) ABSTRACT

A memory device is configured to provide highly available memory and/or storage services. The memory device may comprise memory logic configured to store data redundantly on two or more different storage locations within a memory structure (e.g., a memory chip, package, die, and/or the like). The memory logic may be configured to store data redundantly within different regions of the memory, such that each data block is stored in both a first plane and a second plane of a memory die. The memory logic may be configured to read data from one or more of the redundant storage locations to protect data from loss and/or corruption.

### TECHNICAL FIELD

This disclosure relates to memory storage and, in particular, to a memory system configured to provide highly-available memory and/or storage services within a memory structure, such as a memory die.

### SUMMARY

Data storage systems may protect data from loss and/or corruption. Such systems may provide “highly available” storage services. As used herein, “highly available” storage services refer to storage services that are capable of continuous operation for a desirably long period of time and/or are resistant to failure conditions. Such storage systems may comprise “external data protection components,” which may be configured to ensure that data stored within the system can be accessed despite error conditions and/or failures of one or more storage devices of the system (or failures of particular storage locations therein). The external data protection components may be configured to protect data from loss and/or corruption by, inter alia, distributing the data across two or more independent storage structures. If data cannot be accessed from a storage location within one of the storage structures, the external data protection component accesses (and/or reconstructs) the data from information obtained from storage locations of other storage structures. External data protection components may advantageously protect data from error and/or failure conditions affecting particular storage locations, as well as failures of the storage structures themselves (e.g., a failure of an entire storage device or memory die). However, these components typically impose substantial overhead and complexity. Moreover, the proper configuration, setup, and/or management of external data protection components may require knowledge, skills, and/or access privileges that typical users do not possess. What is needed, therefore, are systems and methods for providing highly-available storage services without the complexity and overhead of external data protection components. What is needed are systems and methods for providing highly-available storage services within the memory structure itself, independent of external data protection components.

Disclosed herein are systems and methods for a memory. The disclosed memory may be configured to implement high-availability storage operations in which data is stored redundantly within the memory structure itself. A high-availability write operation may comprise writing data to two (or more) different physical locations within the memory (e.g., may comprise writing the data to two different sets of physical pages of the memory). A high-availability read operation may comprise reading data from the two or more physical locations (e.g., if the data cannot be read from a first set of physical pages within the memory, the data may be read from a second set of physical pages, and so on). The high-availability storage operations may be performed transparently, such that the high-availability storage operations are implemented by the memory in response to respective commands, and without the need for management by an external data protection component. In some embodiments, high-availability storage operations are managed and/or implemented by memory logic. The memory logic may be embodied within the same structure as the memory (e.g., on the same package, chip, die, and/or the like). The memory may comprise a die having a memory region and a periphery region. The memory region may comprise a plurality of non-volatile memory cells (e.g., a two- or three-dimensional memory cell array). The memory logic may be embodied within the periphery region. The high-availability storage operations disclosed herein may, therefore, be implemented within the memory structure itself and, as such, may protect data from loss and/or corruption independently of external data protection components (and without the complexity and overhead of such components). The highly-available memory disclosed herein may be configured to recover from failures of particular memory locations (physical pages) with little or no overhead. Unlike the external data protection components mentioned above, however, data may not be protected from structure-level failures (e.g., a failure of memory die).

Disclosed herein are embodiments of a memory device. The disclosed memory device may be configured to implement high-availability storage operations within a memory structure (e.g., memory die), independent of external data protection components. The memory device may include a memory die comprising a plurality of memory pages and memory logic configured to store data pages redundantly within the memory die, such that each data page stored within the memory die is written to two physical memory pages of the memory die, including a first physical memory page and a second physical memory page in response to respective commands to write the memory pages received at the memory die. The memory pages may comprise memory cells embodied within a memory region of the memory die. The memory logic may be embodied within a periphery region of the memory die.

In some embodiments, the memory device further comprises address logic configured to associate each data page with at least two physical memory pages of the memory die. The memory die may comprise N memory pages, and the memory logic may be configured to represent that the memory die comprises a different, smaller range of addresses (e.g., N/2 page addresses). The memory logic may represent the smaller address space to a controller, such that the controller issues commands within the smaller address range (e.g., commands to write and/or read data to the N/2 addresses). The address logic may be configured to translate data page addresses to physical memory pages of the memory die, such that each data page address translates to two (or more) different physical memory pages of the memory die. In some embodiments, each data page address corresponds to an address within the range 0 through N/2-1, and the address logic is configured to translate each data page address into a respective address within the range 0 through N. Each data page address X within the range 0 through N/2-1 may, for example, translate to a corresponding first physical memory page address X and to a second physical memory page address X+N/2. The memory die may comprise a first plane and a second plane, and the address logic may be configured to associate each of a plurality of data page addresses with two physical memory pages of the memory die, each data page address being associated with a physical memory page embodied within the first plane and a memory page embodied within the second plane. In some embodiments, the memory die may comprise N physical memory pages; N/2 of the physical memory pages may be embodied within a first plane, and N/2 of the physical memory pages may be embodied within a second plane. The memory logic may report that the memory die comprises a physical storage capacity of N/2 physical memory pages (with an address space ranging from 0 through N/2-1). The address logic may translate each data page address into respective “plane addresses” (e.g., physical memory addresses within the respective planes) such that each data page address X within the range 0 through N/2-1 translates to physical memory page X in the first plane and to physical memory page X in the second plane.

The memory die may be capable of multi-plane operations which may operate on multiple physical memory pages within different respective planes of the memory die. A multi-plane storage operation may comprise reading data from, or writing data to, a plurality of physical memory pages, each physical page embodied within a respective plane of the memory die. In some embodiments, the memory logic may report that the memory die is only capable of single plane operations. The write command may comprise a single-plane write command, and the memory logic may be configured to write the data page to the memory die in a multi-plane write operation configured to program the data page to each of the first physical memory page within a first plane of the memory die and the second physical memory page within a second plane of the memory die. The latency of the multi-plane write operation may be similar to that of a single-plane write operation and, as such, the controller may not be aware that the data was written to the memory in a multi-plane write operation rather than a single-plane write operation. As such, the high-availability, redundant write operation implemented by the memory logic may be transparent to the controller.

In some embodiments, the memory logic is configured to operate in a specified one of a strict redundancy mode and a non-strict redundancy mode. The mode may determine the manner in which the memory logic handles error and/or failure conditions. When operating in the strict redundancy mode, the memory logic may require that each data page be verifiably written to two (or more) physical memory pages. When operating in the non-strict redundancy mode, the memory logic may require that each data page be written to at least one of the two (or more) memory pages associated with the data page. In response to storing a data page of a write command in a first one of two physical memory pages of the memory die and failing to store the data page of the write command in a second one of the two physical memory pages, the memory logic is configured to provide one of: an indication that the write command failed when the memory logic is configured to operate in the strict mode, and an indication that the write command was completed when the memory logic is configured to operate in the non-strict mode.

Disclosed herein are embodiments of a memory system. The disclosed memory system may be configured to provide HA storage services within a memory structure, independent of external data protection components. Embodiments of the memory system include a memory structure comprising a memory region and a periphery region; a plurality of memory pages, each memory page embodied within one of a first plane of the memory region and a second plane of the memory region; and memory circuitry embodied within the periphery region of the memory structure. The memory circuitry may comprise address circuitry configured to associate data pages with memory pages of the memory structure, such that each data page stored within the memory structure is associated with at least two memory pages, the at least two memory pages including a memory page embodied within the first plane of the memory region and a memory page embodied within the second plane of the memory region, and write circuitry configured to replicate data pages for storage within the memory structure, wherein to store a data page within the memory structure, the write circuitry is configured to store the data page on each of the at least two memory pages associated with the data page by the address circuitry, including a memory page embodied within the first plane of the memory region and a memory page embodied within the second plane of the memory region.

The memory circuitry may further comprise read circuitry configured to read data pages stored within the memory structure. The read circuitry may be configured to read a data page by reading one or more of the at least two memory pages associated with the data page by the address circuitry. The read circuitry may be configured to read data from a first one of the at least two memory pages in a first read operation, and to read data from a second one of the at least two memory pages in a second read operation in response to an error pertaining to the first read operation. The write circuitry may be configured to write data to a replacement memory page in response to the error pertaining to the first read operation.

Disclosed herein are embodiments of a method for providing HA storage services. Embodiments of the disclosed method may comprise receiving a command to store a data unit within a memory structure, the memory structure comprising a plurality of memory blocks, each memory block configured to store a respective data unit; and implementing a high-availability write operation in response to the command, the high-availability write operation to write the data unit to at least two memory blocks of the memory structure. The high-availability write operation may comprise addressing at least two memory blocks of the memory structure, including a first memory block and a second memory block, and using write circuitry of the memory structure to perform one or more write operations to write the data unit to each of the at least two memory blocks of the memory structure, including the first memory block and the second memory block. The memory structure may comprise two planes, and implementing the high-availability write operation may comprise addressing memory blocks within each of the planes of the memory structure such that the data unit is written to a memory block within each of the planes of the memory structure. In some embodiments, implementing the high-availability write operation comprises performing a multi-plane write operation configured to write the data unit to both the first memory block and the second memory block. Embodiments of the disclosed method may further comprise implementing the high-availability write command by, inter alia, translating a data unit address to physical addresses of each of the at least two memory blocks of the memory structure, the at least two memory blocks including a memory block embodied within a first plane of the memory structure and a memory block embodied within a second plane of the memory structure.

Embodiments of the disclosed method further comprise implementing a high-availability read operation to read a data unit from a specified data address. The high-availability read operation may comprise converting the specified data address to two or more memory block addresses, the memory block addresses including a primary memory block address and a secondary memory block address, performing a first read operation on the primary memory block address, and performing a second read operation on the secondary memory block address responsive to an error pertaining to the first read operation. In some embodiments, the high-availability read operation further comprises replacing one of the primary memory block and the secondary memory block with a reserve memory block of the memory structure, and using the write circuitry of the memory structure to write data corresponding to the specified data address to the reserve memory block.

In some embodiments, the disclosed method further comprises servicing a request to read a specified data unit address by translating the specified data unit address to two memory blocks, the two memory blocks within different planes of the memory structure, and performing a multi-plane read operation directed to both of the memory block addresses.

The method may further comprise determining a redundancy mode for the command, the redundancy mode comprising one of a lax mode and a strict mode. Implementing the high-availability write operation may further comprise acknowledging completion of the command in response to the data unit being successfully stored within at least one of the two memory blocks of the memory structure and the determined redundancy mode being the lax mode; and returning an indication that the command failed in response to a failure to store the data unit within each of the two memory blocks of the memory structure and the determined redundancy mode being the strict mode.

Disclosed herein are embodiments of a memory system for providing HA storage services. Embodiments of the memory system may comprise means for associating data segments with memory storage locations within a memory die, each data segment being associated with a respective primary memory storage location within the memory die and a respective secondary memory storage location within the memory die; means for storing the data segments within the memory die, each data segment being written to each of the primary memory storage location associated with the data segment and the secondary memory storage location associated with the data segment; and means for accessing data segments stored within the memory die. Accessing a data segment stored within the memory die may comprise performing a first read operation on the primary memory storage location associated with the data segment, and performing a second read operation on the secondary memory storage location associated with the data segment in response to a failure of the first read operation. The means for associating, the means for storing, and the means for accessing may be embodied on the memory die. In some embodiments, the memory storage locations are embodied within a memory region of the memory die. The means for associating, the means for storing, and the means for accessing may be embodied within a periphery region of the memory die.

In some embodiments, the disclosed system further comprises means for selecting an operating mode for the memory system. The selected operating mode may comprise one of a non-high-availability mode, a high-availability mode, a lax high-availability mode, and a strict high-availability mode. The disclosed means for storing the data segments within the memory die may return a completion indicator in response to the command to store a data segment within the memory die. When configured to operate in the non-high-availability mode, the means for storing may acknowledge successful completion of the command in response to writing the data segment to a memory storage location. When configured to operate a high-availability mode, the means for storing may return a completion acknowledgement in response to the data segment being stored within each of the primary and secondary memory storage locations associated with the data segment. When configured to operate in the lax high-availability mode, the means for storing may acknowledge partial completion of the command in response to successfully storing the data segment within one of the primary and the secondary memory storage locations, and failing to store the data segment within the other one of the primary and secondary memory storage locations. When configured to operate in the strict high-availability mode, the means for storing may acknowledge successful completion of the memory command response to verifying that the data segment was written to both of the primary and secondary memory storage locations. The means for storing may be configured to write the data segment to a replacement memory storage location in response to a failure to write the data segment to either of the primary and the secondary memory storage locations. When configured to operate in the strict high-availability mode, the means for storing may return an indication that the memory command failed in response to failing to verify that the data segment was successfully written to both of the primary and secondary memory storage locations.

The foregoing is provided for purposes of summarizing some embodiments to provide a basic understanding of aspects of the subject matter described herein. The above-described features are merely examples and should not be construed as narrowing the spirit or scope of the subject matter in this disclosure in any way. Other features, aspects, and advantages of the subject matter described herein will become apparent from the following Detailed Description, Figures, and Claims.

### BRIEF DESCRIPTION OF FIGURES

FIG. 1A is a schematic block diagram depicting embodiments of a memory system configured to provide high-availability memory and/or storage services;

FIG. 1B is a schematic block diagram depicting embodiments of a memory system configured to provide high-availability memory and/or storage services by use of a plurality of different sections of a memory structure;

FIG. 1C is a schematic block diagram depicting embodiments of a memory system configured to provide high-availability memory and/or storage services;

FIG. 1D is a schematic block diagram depicting embodiments of a memory system;

FIG. 2 is a schematic block diagram depicting embodiments of a memory system configured to provide highly-available memory and/or storage services within a multi-plane memory structure;

FIG. 3 is a flow diagram of one embodiment of a method for implementing high-availability memory and/or storage operations within a memory structure;

FIG. 4 is a flow diagram of one embodiment of a method for implementing memory and/or storage operations within a memory structure;

FIG. 5 is a flow diagram of another embodiment of a memory for implementing memory and/or storage operations within a memory structure; and

FIG. 6 is a schematic block diagram depicting further embodiments a memory system configured to provide highly-available memory storage services.

### DETAILED DESCRIPTION

Various embodiments will be described more fully with reference to the accompanying drawings. The inventive concepts disclosed herein, however, may be embodied in many different forms and should not be construed as limited to the embodiments set forth herein. Rather, these embodiments are provided so that this disclosure will be thorough and complete, and will fully convey the scope of the inventive concept to those skilled in the art.

A memory device may be configured to provide high-availability memory and/or storage services. As used herein, “high-availability” or “highly-available” (HA) refers to characteristics of a memory and/or storage system in which data is protected from loss and/or corruption. Data stored in a HA memory and/or storage system may be protected from loss due to a single point of failure (e.g., a failure in a particular memory storage location). Some data storage systems implement high-availability by, inter alia, storing data on two or more different memory and/or storage systems. Such approaches to HA may be effective at preventing data loss, but can impose significant overhead and complexity. The memory device disclosed herein may be configured to provide HA memory services within the memory system itself (e.g., within the memory structure, memory die, or the like). The disclosed memory system may, therefore, provide HA memory and/or storage services independently of external devices, controllers, and/or the like (and without the overhead and complexity of conventional HA systems).

In some embodiments, the disclosed memory device may be configured to write data to two (or more) different memory storage locations within a memory structure. The memory storage locations may in different sections or “failure domains.” As used herein, a “failure domain” refers to a section of a memory device that is subject to one or more failure conditions. A “failure domain” may, for example, refer to one or more of a chip, bank, package, die, plane, block, page, and/or the like.

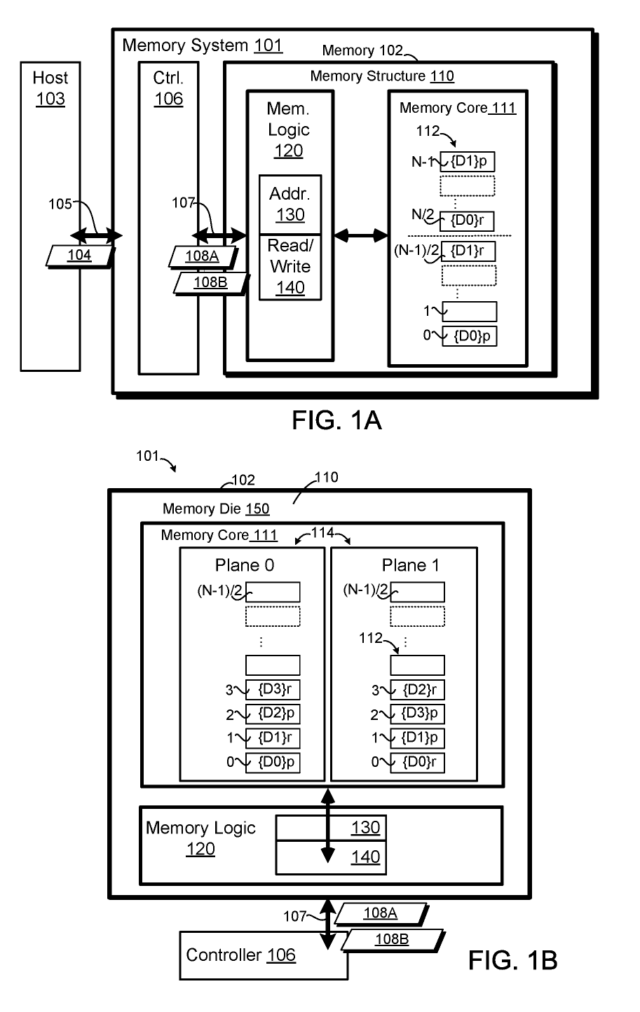

FIG. 1A is a schematic block diagram depicting embodiments of memory system 101 configured to provide highly-available memory and/or storage services. The memory system 101 may comprise a non-volatile memory system configured to interface with a host 103. The host 103 may comprise a computing device, which may include, but is not limited to: a server computing device, a personal computing device, a mobile computing device (e.g., a smartphone, a tablet, or the like), an embedded computing device, a virtual computing system (e.g., a virtual machine, a virtual desktop), a virtualization environment (e.g., a virtualization kernel, a hypervisor), and/or the like.

In some embodiments, the memory system 101 may be embedded within the host 103 and/or may comprise an internal component of the host 103. The memory system 101 may comprise an on-board memory, on-board storage, integrated memory, integrated storage, a memory module, a storage module, and/or the like. The memory system 101 may comprise an add-on device, such as an add-on storage device, an add-on memory device, a peripheral device, or the like, and may be configured to be coupled to the host 103 through one or more of an on-board interconnect, a system interconnect, an external interconnect, a remote interconnect, and/or the like. Alternatively, or in addition, the memory system 101 may be separate from and/or independent of the host 103; the memory system 101 may be embodied as a device, apparatus, and/or system that is separate and/or independent from one or more computing devices, apparatus, and/or systems comprising the host 103. The memory system 101 may comprise a memory device, a storage device, an external memory device, an external storage device, a memory appliance, a storage appliance, a server, a memory server, a storage server, a network-attached memory device, a network-attached storage device, a cache device, a cache appliance, and/or the like. Although FIG. 1A depicts a single host 103, the disclosure is not limited in this regard. The memory system 101 could be communicatively coupled to any number of hosts 103 (e.g., may be shared between a plurality of hosts 103).

The memory system 101 may be communicatively coupled to the host 103 through an interconnect 105. The interconnect 105 may include, but is not limited to, an input/output (I/O) bus, an I/O controller, a local bus, a host bridge (Northbridge, Southbridge, or the like), a front-side bus, a peripheral component interconnect (PCI), a PCI express (PCI-e) bus, a Serial AT Attachment (serial ATA or SATA) bus, a parallel ATA (PATA) bus, a Small Computer System Interface (SCSI) bus, a Direct Memory Access (DMA) interface, an IEEE 1394 (FireWire) interface, a Fiber Channel interface, a Universal Serial Bus (USB) connection, and/or the like. In some embodiments, the memory system 101 is communicatively coupled to the host 103 through an electronic communication network. The interconnect 105 may, therefore, comprise one or more of: a network, a network connection, a network interface, a storage network interface, a Storage Area Network (SAN) interface, a Virtual Storage Area Network (VSAN) interface, a remote bus, a PCE-e bus, an Infiniband interface, a Fibre Channel Protocol (FCP) interface, a HyperSCSI interface, a remove DMA (RDMA) interface, and/or the like.

The memory system 101 comprises a memory 102 whose operations are controlled by, inter alia, a controller 106. The controller 106 may be coupled to the memory 102 through, inter alia, a memory core interconnect 107. The memory core interconnect 107 may comprise any suitable interconnect for coupling the controller 106 to the memory 102, memory structure 110, and/or memory logic 120, and may include, but is not limited to: a bus, a parallel bus, a serial bus, and/or the like.

As disclosed in further detail herein, the memory 102 may comprise a plurality of physical memory pages (memory pages 112), which may be capable of storing data, and having data retrieved therefrom. The memory pages 112 may be comprised of non-volatile memory cells distributed over and/or within a memory structure 110. The controller 106 may include one or more state machines, data registers, control registers, volatile Random Access Memory (RAM), static RAM (SRAM), control logic, control circuitry, firmware, and/or the like.

The memory pages 112 of the memory system 101 may be embodied on and/or within a memory structure 110. As used herein, a memory structure 110 refers to structural element(s) that embody the memory storage pages 112 (within a memory core 111) and/or corresponding memory logic 120. The memory structure 110 may include, but is not limited to: a chip, a package, a die, a substrate, a semiconductor substrate, a semiconductor, a semiconductor wafer, a Flash memory die, a NAND-Flash die, a NOR-Flash die, and/or the like. The memory logic 120 may comprise circuitry for implementing memory operations on memory pages 112 of the memory structure 110 (e.g., operations to program, read, and/or erase selected memory pages 112). In some embodiments, the memory pages 112 are formed on and/or within the memory structure 110. Similarly, circuitry and other elements comprising the memory logic 120 may be formed on and/or within the memory structure 110. Both the memory core 111 and the memory logic 120 of the memory system 101 may be embodied within the same memory structure 110 (e.g., may be formed on and/or within a same memory structure 110). In some embodiments, the memory storage elements 112 are embodied within a memory region or memory core 111 of the memory structure 110 and the memory logic 120 are embodied within a periphery region of the memory structure 110.

Although FIG. 1A depicts a memory system 101 comprising a single memory 102 and/or memory structure 110, the disclosure is not limited in this regard and encompasses embodiments that include any number of memories 102 and/or memory structures 110 (e.g., four, eight, or more memory structure 110), each of which may comprise a respective memory core 111 (comprising memory storage pages 112) and respective memory logic 120.

The controller 106 may be configured to receive commands 104 pertaining to the memory system 101 via the interconnect 105. The commands 104 may comprise commands to store data within the memory structure 110, commands to read data from the memory structure 110, commands pertaining to a configuration of the memory system 101, commands requesting status information pertaining to the memory system 101, commands to transfer data to and/or from the memory system 101, and so on. The controller 106 may be configured to provide data stored within the memory system 101 through the interconnect 105, which may include, but is not limited to: data read from the memory system 101, status information pertaining to the memory system 101, configuration information pertaining to the memory system 101, and so on. Although not depicted in FIG. 1A to avoid obscuring the details of the illustrated embodiments, the controller 106 may comprise one or more interface components configured to communicatively couple the controller 106 to the interconnect 105. The controller 106 may, for example, be configured to manage data transfers to and/or from the memory system 101. The controller 106 may comprise an I/O controller, an I/O buffer, a read buffer, a write buffer, a DMA controller, an RDMA controller, and/or the like. The controller 106 may be further configured to power the memory structure 110 through the interconnect 107. Alternatively, the memory structure 110 may be powered through a separate power source and/or connection (not shown in FIG. 1A to avoid obscuring the details of the illustrated embodiments).

As disclosed above, a memory page 112 refers to any structure capable of storing data and/or having data retrieved therefrom. The memory pages 112 may comprise any suitable type of memory including, but not limited to: volatile memory, non-volatile memory, non-transitory memory, solid-state memory, Flash memory, NAND-type Flash memory, NOR-type Flash memory, Programmable Metallization Cell (PMC) memory, Silicon-Oxide-Nitride-Oxide-Silicon (SONOS) memory, Resistive RAM (RRAM) memory, Floating Junction Gate RAM (FJG RAM), ferroelectric memory (FeRAM), magnetoresistive memory (MRAM), phase change memory (PRAM), Electrically Erasable Programmable Read-Only Memory (EEPROM), and/or the like.

Each of the memory pages 112 of FIG. 1A may be capable of storing a particular amount and/or quantum of data within a “data area” thereof. The data area may be configured to store one or more bits, bytes, words, pages, and/or other data structure. The amount of data capable of being stored within the data area of a memory page 112 may be referred to as a block, a data block, a segment, a data segment, a unit, a data unit, a sector, a data sector, a page, a data page, a packet, a data packet, and/or the like. The data area of the respective memory pages 112 may correspond to a smallest granularity of memory read and/or write operations that can be performed within the memory structure 110. The size of the data area of the memory pages 112 may be referred to as the block size of the memory structure 110 (or segment size, unit size, sector size, page size, packet size, etc.). The controller 106 may be configured to store and/or retrieve blocks or data blocks from respective memory pages 112 by use of, inter alia, memory commands 108A and 108B.

In some embodiments, data may be stored within the memory pages 112 in accordance with a particular data configuration, which may correspond to one or more of: a bit order, a byte order, a page order, and/or the like of data stored within the respective memory pages 112. For example, data may be stored within the memory pages 112 according to a particular endianness (e.g., big endian, little endian, mixed endian, and/or the like).

The memory pages 112 may be embodied within the memory core 111 of the memory structure 110. The memory core 111 may comprise, but is not limited to, one or more of: a memory array, an array of two-terminal memory cells, multi-terminal memory cells, a cross-point memory array, a two-dimensional memory array, a three-dimensional memory array, a memory plane, a memory bay, a memory module, and/or the like. The memory pages 112 may comprise one or more discrete memory storage elements, which may include, but are not limited to: memory cells, capacitive memory cells, resistive memory cells, magnetoresistive memory cells, phase-change memory cells, ferroelectric capacitive memory cells, binary-value cells, multi-value cells, and/or the like. The memory structure 110 may comprise structure(s) suitable for formation of the memory core 111 and/or memory pages 112, such as one or more semiconductor substrates, wafers, die, NAND-Flash die, NOR-Flash die, and/or the like.

The memory structure 110 further comprises memory logic 120, which may be configured to, inter alia, implement memory operations pertaining to the memory pages 112 embodied within the memory core 111. The memory logic 120 may be configured to write and/or program data to selected memory pages 112, read data from selected memory pages 112, erase and/or initialize selected memory pages 112 and/or groups of memory pages 112 (e.g., memory pages 112 in a common erase block or other grouping), manage error conditions pertaining to the memory pages 112 (e.g., detect write, program, and/or read errors), determine status information pertaining to the memory pages 112 (e.g., write, program, and/or read latency, error rate, wear level, program-erase count, and so on). Circuitry and/or other elements of the memory logic 120 may be embodied within a periphery region of the memory structure 110.

In the FIG. 1A embodiment, the memory logic 120 comprises address logic 130 and read/write logic 140. The read/write logic 140 may be configured to implement memory operations on selected memory pages 112 of the memory core 111. The memory operations may include writing and/or programming data on selected memory pages 112, reading and/or sensing data from selected memory pages 112, erasing memory pages 112, and so on. The address logic 130 may be configured to address selected memory pages 112, such that the read/write logic 140 can perform corresponding memory operations thereon. As disclosed in further detail herein, addressing a memory page 112 may comprise selecting the memory page 112, coupling the memory page 112 to the read/write logic 140 (e.g., read/write circuitry of the read/write logic 140), routing signals to the memory page 112 (e.g., program pulses, sense signals, bias signals, and so on), and the like.

The memory logic 120 may perform memory operations in response to memory commands received via the interconnect 107. In some embodiments, the memory logic 120 is configured to implement a memory command to write data to the memory 102 (e.g., a write command 108A). In response to a write command 108A, the memory logic 120 may be configured to, inter alia: a) use the address logic 130 to address a memory page 112 corresponding to the command 108A, and b) use the read/write logic 140 to perform write operation(s) to store data of the write command 108A on the addressed memory page 112. The write operation(s) may comprise programming data on the addressed memory page 112A, which may comprise one or more of: applying program pulses to the addressed memory page 112, applying a sequence of program pulses to the addressed memory page 112, and so on. The write operation(s) may further comprise verifying data written to the addressed memory page 112 (e.g., by reading data from the addressed memory page 112).

The memory logic 120 may implement memory commands to read data from the memory system 101 (e.g., read commands 108B). In response to a read command 108, the memory logic 120 may be configured to, inter alia: a) use the address logic 130 to address a memory page 112, and b) use the read/write logic 140 to perform read operation(s) on the addressed memory page 112. The read operation(s) may comprise biasing the addressed memory page 112, applying one or more read signals (e.g., read pulses), sensing signals returned from the addressed memory page 112, and/or the like. The read operation(s) may further comprise verifying data read from the addressed memory page 112A by, inter alia, detecting read errors, correcting errors detected in the data (if any), reporting uncorrectable errors detected in the data (if any), and so on.

As disclosed above, the address logic 130 may be configured to address memory pages 112 responsive to memory commands, such as write commands 108A and/or read commands 108B. The address logic 130 may address memory pages 112 based on addressing information of the memory commands. Memory commands issued to the memory logic 120 of the memory 102 may, in some embodiments, include addressing information, which may be used by the address logic 130 to address corresponding memory page(s) 112 within the memory structure 110. In the FIG. 1A embodiment, the memory 102 may comprise N memory pages 112, which may be identified using respective identifiers, numbers, and/or offsets (e.g., 0 through N-1, as illustrated in FIG. 1A). The controller 106 may reference the memory pages 112 using a corresponding set of “block addresses” (e.g., 0 through N-1). The address logic 130 may use such block addresses to address corresponding memory page(s) 112 within the memory structure 110. Although particular examples of addresses and/or addressing schemes are disclosed herein, the memory system 101 is not limited in this regard, and could be adapted to address memory pages 112 using any suitable addresses and/or in accordance with any suitable addressing scheme.

As disclosed above, the memory logic 120 may be configured to write data blocks on respective memory pages 112 of the memory structure 110 responsive to write commands 108A. The memory logic 120 may be further configured to read data written to such memory pages 112 responsive to read commands 108B. A memory command 108 to read data from a memory page 112 may result in a read failure. As used herein, a “read failure” refers to a failure to read data stored within a memory page 112 of the memory 102. A read failure may occur due to any number of reasons, including, but not limited to: a hardware failure, an addressing failure (e.g., a fault in selection, interconnect, and/or routing logic of the memory core 111), a read sense failure, bit errors, uncorrectable bit errors, a verification failure (e.g., decode errors, signature mismatch), and/or the like. A read failure may result in data loss or corruption.

In some embodiments, data may be protected from loss and/or corruption by use of, inter alia, external data protection components (not shown in FIG. 1A to avoid obscuring the details of the illustrated embodiments). As mentioned above, an “external data protection component” refers to a system, device, logic, circuit, software, firmware, or other component that is external to the memory 102 and/or memory structure 110, such as the controller 106, host 103, and/or the like. An external data protection component may be configured to provide HA memory and/or storage services by use of a plurality of different memory and/or storage structures (e.g., a plurality of memory systems 101, memory structures 110, and/or the like). External data protection may comprise storing data (and/or information from which the data can be reconstructed) on two of more different memory and/or storage devices. Examples of external data protection components include Redundant Array of Inexpensive Disks (RAID) controllers, Just a Bunch of Disks (JBOD) managers, backup software, mirrored storage systems, cache controllers, and/or the like. Although external data protection components may protect data from loss due to failure of a particular storage location or an entire device, such components can involve substantial overhead and complexity. For example, a RAID system may require an external data protection component (a RAID controller) to manage, configure, and operate a plurality of different devices, and may impose additional storage mapping layer(s) (e.g., map data to/from respective RAID stripes). For example, write commands issued to the RAID controller may involve processing the data (e.g., formatting the data into a RAID stripe, generating error correction information, and so on), issuing write commands to store respective portions of the RAID stripe within each of a plurality of different storage structures (e.g., issuing write commands to controllers of the respective storage structures), and recording mappings to associate the data with the RAID stripe. Although external data protection components may be capable of protecting data from error and/or failure conditions affecting particular storage locations, as well as failures of the storage structures themselves, their overhead, complexity, and cost, may not be warranted in many situations.

The memory system 101 disclosed herein may be configured to implement HA memory operations within the memory 102 itself (e.g., within the memory structure 110), and may do so independently of external data protection components (e.g., independently of the controller 106, host 103, other external controller(s), and/or the like). The memory system 101 disclosed herein may be configured to protect data from loss and/or corruption by, inter alia, storing data redundantly within the memory structure 110. Accordingly, data may be protected from loss and/or corruption, without the overhead and complexity of external data protection components. In some embodiments, data are protected from loss and/or corruption by use of a “highly-available” memory die (e.g., NAND-Flash die), which may be configured to redundantly store data written thereto within two (or more) different memory storage locations of the NAND-Flash die. Data written to the HA memory die disclosed herein may, therefore, be protected from loss and/or corruption due to a failure of one of the storage locations. In some embodiments, the HA memory disclosed herein may be configured to store data within different sections of the NAND-Flash die. The sections may correspond to different failure domains (e.g., may be subject to different failure conditions). The sections of the memory structure may correspond to different planes of a NAND-Flash die. Data stored within the disclosed HA memory system may, therefore, be protected from loss and/or corruption due to failure conditions within one of the failure domains (e.g., a failure of one of the planes of the NAND-Flash die). The memory system 101 may be capable of recovering from failures of particular storage locations within the memory structure 110 but, unlike more complex, external data protection components and/or systems, may not be capable of recovering from a failure of the memory structure 110.

In the FIG. 1A embodiment, the memory logic 120 may be configured to provide HA memory and/or storage services within the memory 102, independently of component(s) external to the memory structure 110 (e.g., independently of the controller 106, host 103, an external data protection system, and/or the like). The memory logic 120 may be configured to implement HA memory operations independently of external components, such as the controller 106, host 103, and/or the like. Providing highly-available memory and/or storage services may comprise writing data on two (or more) different memory pages 112 of the memory 102 (e.g., writing data on a first set of memory pages 112 and writing a redundant copy of the data on a second set of memory pages 112). In response to a write command 108A to store a data block within the memory 102, the memory logic 120 may be configured to, inter alia: a) use the address logic 130 to address two (or more) memory page(s) 112, and b) use the read/write logic 140 to perform write operation(s) to store the data unit on the each of the two (or more) memory pages 112. In some embodiments, the memory logic 120 performs separate write operation(s) on each of the two (or more) memory pages 112. Alternatively, the memory logic 120 may be configured to write to the two (or more) memory pages in parallel and/or with some degree of concurrency (e.g., in a multi-plane write operation, as disclosed in further detail herein).

Providing highly-available memory and/or storage services may further comprise reading data from two (or more) different memory pages 112. In response to a read command 108B, the memory logic 120 may be configured to, inter alia: a) use the address logic 130 to address two (or more) memory pages 112, and b) use the read/write logic 140 to perform read operation(s) to read data from one or more of the memory pages 112. The read operation(s) may comprise detecting read failure pertaining to one or more of the memory pages 112, as disclosed above. In response to a read failure, the memory logic 120 may be configured to read the data from other(s) of the two (or more) memory units 112. In some embodiments, the read operation(s) are performed separately and/or in response to read failures pertaining to others of the two (or more) memory pages 112. In other embodiments, the memory logic 120 may be configured to read data from each of the two (or more) memory pages 112 regardless of read errors and/or failures pertaining to the first and/or second memory pages 112. The memory logic 120 may be configured to read data from the two (or more) storage units 112 in parallel and/or concurrently.

As disclosed above, implementing highly-available memory operations may comprise addressing two (or more) memory pages 112 in response to a memory command. The address logic 130 may be configured to implement highly-available memory operations by, inter alia, associating address information of memory commands with two (or more) memory pages 112 of the memory structure 110. As disclosed above, memory commands received at the memory logic 120 may comprise and/or reference block and/or memory address information, which may include, but is not limited to: block numbers, block offsets, block addresses, memory addresses, memory offsets, and/or the like. The address logic 130 may be configured to associate such address information with two (or more) different sets of memory pages 112. In some embodiments, the address logic 130 implements “redundant addressing” between address information of the memory commands and the memory pages 112 of the memory structure 110. As used herein, “redundant addressing” refers to a one-to-many addressing scheme in which each identifier of a first set corresponds to two (or more) identifiers of a second set. In the FIG. 1A embodiment, the address logic 130 may implement a one-to-two addressing scheme in which address information of memory commands has a one-to-two relationship to the memory pages 112 within the memory structure 110. The redundant addressing scheme may comprise translating a block address of a memory command (e.g., a block number, identifier, offset, and/or the like) to two different memory storage locations 112. The address logic 130 may be configured to translate and/or convert a block address to: a) a first memory page 112 addressed using the block address, and b) a second memory page 112 addressed by translating the block address. Translating the block address may comprise any suitable translation operation, scheme, and/or technique including, but not limited to: an offset, a modulo operation, a look up table, a translation map, a transform, and/or the like.

In the FIG. 1A embodiment, the address logic 130 may implement a redundant addressing scheme in which an offset of N/2 is applied to address information of memory commands (e.g., applied to block numbers, offsets, and/or other address information of the memory commands). As illustrated in FIG. 1A, the memory logic 120 may implement a write command 108A directing the memory logic 120 to write data block (D4) at block (0) by, inter alia: a) using the address logic to redundantly address a first memory page 112 (0) and a second memory page 112 (N/2) corresponding to block (0), and b) performing write operation(s) to write the data (D4) to both of the first and second memory pages 112. The redundant addressing scheme implemented by the address logic 130 may address the first memory page 112 (0) based on the provided address information, and may address the second memory page 112 (N/2) by applying an offset of N/2 to block (e.g., applying an offset of N/2 to block 0), as disclosed above. In another example, the memory logic 120 implements a write command 108A to write (D1) to block (N-1)/2 by writing the data block (D1) on a first memory page 112 (N-1)/2 and a second memory page 112 (N-1), in accordance with the redundant addressing scheme disclosed above. In some embodiments, the first memory page 112 may be referred to as the “primary” memory page 112, and the second memory page 112 may be referred to as a “secondary” or “redundant” memory page 112. Data written to the primary memory page 112 may be referred to as a primary copy of the data (illustrated as {D0}p, {D1}p in FIG. 1A). Data written to the “secondary” or “redundant” memory page 112 may be referred to as a “secondary” or “redundant” copy of the data (illustrated as {D0}r, {D1}r in FIG. 1A).

The memory logic 120 may implement highly-available read commands 108B. The memory logic 120 may implement such commands in accordance with a redundant addressing scheme, as disclosed above. The memory logic 120 may implement a read command 108B to read data from block (0) by, inter alia: a) using the address logic 130 to address the first memory page 112 (0) and the second memory page 112 (N/2), and b) using the read/write logic 140 to perform read operation(s) on the first and/or second memory pages 112. In some embodiments, the read/write logic 140 attempts to read the primary copy of the data from the first memory page 112 (0), and only reads the redundant copy of the data from the second memory page 112 (N/2) in response to a read failure. In another example, the memory logic 120 implements a read command 108B for block (N-1)/2 by: reading the primary copy of the data from the memory page 112 (N-1)/2, and reading the second memory page 112 (N-1) in response to a read failure.

Although particular examples of redundant addressing schemes and/or techniques are described herein, the disclosed embodiments are not limited in this regard. As disclosed above, the address logic 130 could be adapted to use any suitable scheme and/or technique for implementing one-to-many addressing between address information of memory commands and the memory pages 112 of the memory 102. In some embodiments, the address logic 130 is configured to implement a variable and/or dynamic addressing scheme in which first and/or second memory pages 112 are alternated in order to, inter alia, wear level the memory pages 112. For example, the memory logic 120 may alternate between read operations between memory pages 112 corresponding to a particular block such that the read operations are evenly distributed between the respective memory pages 112. The memory logic 120 may be further configured to adapt the redundant addressing scheme to distribute write operations among the N memory pages 112 of the memory structure 110.

As disclosed above, implementing highly-available memory operations may comprise associating block(s) referenced by memory commands with two (or more) memory pages 112 by use of, inter alia, a one-to-many redundant addressing scheme. When configured to implement HA memory operations as disclosed herein, the memory logic 120 may be configured to represent that the memory structure 110 comprises fewer than N memory pages 112. The memory logic 120 may indicate that the memory structure 110 includes N/M memory pages 112, where M is the number of memory pages 112 associated with each block. In the FIG. 1A embodiment in which the memory logic 120 associates each block with two memory pages 112, the memory logic 120 may represent that the memory 102 includes N/2 memory pages 112 (e.g., a range of memory pages 112 from 0 through (N-1)/2). The memory logic 120 may, therefore, represent that that the memory 102 includes only N/2 memory pages 112 rather than the full set of N addressable memory pages 112. The set, range, and/or extent of memory pages 112 that the memory logic 120 represents as being available for memory operations may be referred to as a “memory address space,” “data segment address space,” “page address space,” or “external address space” (i.e., a memory address space visible to components outside of the memory structure 110, such as the controller 106 and/or host 103). The memory logic 120 may receive memory commands that reference blocks outside of the memory address space represented by the memory logic 120. For example, the memory logic 120 may receive a write command 108A or read command 108B that references memory page and/or block greater than (N-1)/2. The memory logic 120 may be configured to respond to memory commands that reference memory pages and/or blocks that are outside of the represented memory address space of the memory structure 110. By way of non-limiting example, the memory logic 120 may respond to such a command by one or more of: returning an error code (e.g., an error code indicating that the memory page or block is out-of-range), translating and/or converting the address into the represented memory address space (e.g., into range 0 through (N-1)/2 using a modulo operator), implementing a non-HA operation (e.g., write data to only one memory page 112), modifying the operating mode and/or configuration of the memory logic 120 from an HA operating mode to a standard, non-HA operating mode, and/or the like.

FIG. 1B is a schematic block diagram of embodiments of a memory system 101 configured to implement highly-available memory operations within respective planes of a memory die. In the FIG. 1B embodiment, the memory structure 110 comprises a memory die 150, such as a NAND-Flash memory die. The memory logic 120 may be embodied within a periphery region of the memory die 150 (e.g., a periphery region of the NAND-Flash memory die). The memory die 150 comprises N memory pages 112. The memory pages 112 may be evenly distributed between plane 0 and plane 1. As illustrated in FIG. 1B, each plane 0 and 1 comprises N/2 memory pages (e.g., ranging from 0 through (N-1)/2). The memory logic 120 may be configured to perform multi-plane operations on planes 0 and 1, which may comprise writing data to memory pages 112 within planes 0 and 1 in parallel and/or concurrently. The memory pages 112 of plane 0 may be subject to different failure modes and/or conditions than the memory pages 112 of plane 1 (and vice versa). As such, plane 0 and plane 1 may comprise respective failure domains of the memory die 150. As disclosed in further detail herein, when configured for HA operation, the memory logic 120 may be configured to store data redundantly within different sections 114 of the memory die 150. The sections 114 may correspond to different failure domains, as disclosed herein. In some embodiments, the sections 114 comprise separate semiconductor regions, planes, and/or the like. The memory logic 120 may be configured such that each data block written to the memory 102 is stored within a memory page 112 of plane 0 and a memory page 112 of plane 1. The data blocks may, therefore, be protected from loss and/or corruption due to a failure of one of the memory pages 112 and/or a failure within one of the sections 114 (e.g., a failure of one of the planes 0 or 1).

As disclosed above, when configured for HA operation, the address logic 130 may be configured to associate address information of memory commands with respective memory pages 112 within each plane 0 and 1. The redundant addressing scheme implemented by translation circuitry 132 may comprise addressing a first memory page 112 in plane 0 (or plane 1) and addressing a second memory page 112 in plane 1 (or plane 0) for each block referenced in a memory command.

A write command 108A may direct the memory logic 120 to write data block (D0) to block [0,0] (e.g., block 0 of plane 0). In response, the memory logic 120 may, inter alia: a) use the address logic 130 to address a first memory page 112 [0,0] (memory page 0 in plane 0) and to address a second memory page 112 [1,0] (memory page 0 in plane 1), and b) use the read/write logic 140 to perform first memory operation(s) to store a “primary” copy of the data (e.g., {D0}p) on the first memory page 112 [0,0], and perform second memory operation(s) to store a “redundant” copy of the data (e.g., {D0}r) to the second memory page 112 [1,0]. In some embodiments, the first and second write operation(s) may be performed in parallel and/or concurrently in a multi-plane write operation on planes 0 and 1. Alternatively, the first and second write operation(s) may be performed separately and/or according to various degrees of concurrency.

A read command 108B may direct the memory logic 120 to read data from block [0,0]. In response, the memory logic 120 may, inter alia: a) use the address logic 130 to address the first and second memory pages 112 [0,0] and [1,0] within planes 0 and 1, respectively, and b) use the read/write logic 140 to perform first and/or second read operations on the memory pages 112 [0,0], [1,0] to read data therefrom. The first and/or second read operations may comprise a multi-plane read operation performed in parallel and/or concurrently on planes 0 and 1. Alternatively, or in addition, the first and second read operation(s) may be performed separately and/or according to various degrees of concurrence. The memory logic 120 may, in some embodiments, perform the second read operation responsive to read failure. The memory logic 120 may alternate between reading the data from the first and/or second memory page 112 [0,0] or [1,0] in order to, inter alia, level read operations performed thereon, as disclosed herein.

In another embodiment, a write command 108A may direct the memory logic 120 to write data block (D1) to a block in plane 1 (e.g., to block [1,1]). The memory logic 120 may implement the write command 108A by, inter alia: a) addressing first and second memory pages 112 [1,1] and [0,1] within planes 1 and 0, respectively, and b) using the read/write logic 140 to perform first and/or second write operations to write the data D1 on the memory pages 112 [1,1] and [0,1]. As illustrated in FIG. 1B, the memory page 112 [1,1] of plane 1 comprises the “primary” copy of the data block, and the memory page 112 [0,1] may comprise the “redundant” copy of the data block. The first and/or second write operation may comprise a multi-plane write operation, as disclosed above. The memory logic 120 may service a subsequent read command 108B to block [1,1] by performing first read operation(s) on memory page 112 [1,1] and performing second read operation(s) on memory page 112 [0,1] responsive to a read failure condition pertaining to memory page 112 [1,1]. Alternatively, the address logic 130 may alternate read operation(s), as disclosed above.

When configured to implement highly-available memory operations, the memory logic 120 may report that the memory 102 comprises fewer than N memory pages 112, as disclosed herein. In the FIG. 1B embodiment, the memory logic 120 may be configured to report that the memory structure 110 comprises N/2 memory pages 112 within a single plane (and/or is only capable of implementing single-plane memory commands).

In other embodiments, the memory logic 120 may report that the memory structure 110 is capable of performing multi-plane memory operations, which may comprise performing memory operations on planes 0 and 1 in parallel and/or concurrently, as disclosed herein. In such embodiments, the address logic 130 may implement a redundant addressing scheme configured for multi-plane operation (e.g., a multi-plane redundant addressing scheme) in which each block address corresponding to plane 0 translates to an “unaddressed” memory page 112 within plane 1 (and vice versa).

In the FIG. 1B embodiment, a write command 108A may direct the memory logic 120 to write blocks (D2) and (D3) to block (2) of planes 0 and 1 in a multi-plane write operation (e.g., write data (D2) on memory page 112 [0,2] in plane 0 and write data (D3) on memory page 112 [1,2] in plane 1). The address logic 130 may be configured to implement a multi-plane redundant addressing scheme in which the “primary” block addresses [0,2] and [1,2] of the multi-plane write command 108A correspond to “redundant” block addresses [1,3] and [0,3], respectively. The memory logic 120 may implement the multi-plane write command 108A by performing two multi-plane write operations. The memory logic 120 may write the data block (D2) to planes 0 and 1 in a first multi-plane write, and may write the data block (D3) to planes 1 and 0 in a second multi-plane write. The first multi-plane write may comprise, inter alia: a) using the address logic 130 to address a first memory page 112 [0,2] within plane 0 for storage of the primary copy of the data block (D2), and to address a second memory page 112 [1,3] within plane 1 for storage of the redundant copy of the data block (D2); and b) using the read/write logic 140 to perform a first multi-plane write operation to write the data block (D2) on both memory pages 112 [0,2] and [1,3]. The second multi-plane write may comprise, inter alia: a) using the address logic 130 to address a first memory page 112 [1,2] within plane 1 for storage of the primary copy of data block (D3), and to address a second memory page 112 [1,3] within plane 0 for storage of the redundant copy of data block (D3); and b) using the read/write logic 140 to perform a second multi-plane write operation to write the data block (D3) on the first and second memory pages 112 [1,3] and [0,2].

The memory logic 120 may be further configured to service multi-plane read commands 108B by, inter alia, performing two (or more) multi-plane read operations. The memory logic 120 may implement a multi-plane read command 108B of blocks [0,2] and [1,2] by performing a first multi-plane read operation on memory pages 112 [0,2] and [1,2] that comprise the “primary” copy of data blocks (D2) and (D3). The memory logic 120 may perform a second multi-plane read operation (or a single-plane read operation) responsive to a read failure. The address logic 130 may be further configured to alternate read operations between the first and/or second memory pages 112 [0,2], [1,2] and [1,3] [0,3], as disclosed herein.

FIG. 1C is a schematic block diagram depicting further embodiments of a memory system 101 configured to provide highly-available memory and/or storage services. In the FIG. 1C embodiment, the memory structure 110 comprises a plurality of memory pages 112 embodied within a memory array 151 of the memory core 111. The memory array 151 may comprise a plurality of NAND structures (e.g., NAND strings) arranged into respective memory pages 112.

The memory structure 110 includes memory logic 120, which may comprise address logic 130 and read/write logic 140. The read/write logic 140 may be configured to implement memory operations on selected memory pages 112, which, as disclosed above, may include performing write operations to store and/or program data on selected memory pages 112, performing read operations to read and/or sense data stored on selected memory pages 112, erase and/or initialize selected memory pages 112 (and/or groups of memory pages 112), and so on. The read/write logic 140 may perform such memory operations by, inter alia, the use of memory signals 129, which may be transmitted to and/or from selected memory pages 112 of the memory core 111. The memory signals 129 may include, but are not limited to: write signals, write pulses, program signals, program pulses, read signals, read pulses, sense signals, sense pulses, bias signals, bias pulses, and/or the like. Although not depicted in FIG. 1C to avoid obscuring the details of the illustrated embodiments, the read/write logic 140 may comprise one or more read/write circuits, sense circuits, sense amplifier circuits, driver circuits, bias circuits, and/or the like, which may be embodied within the memory structure 110 with the memory core 111.

The address logic 130 may be configured to address memory pages 112 of the memory core 111. As used herein, addressing a memory page 112 may include, but is not limited to: coupling an addressed memory page 112 to the read/write logic 140 (e.g., to read/write circuitry of the read/write logic 140), electrically coupling the addressed memory page 112 to the read/write logic 140, selecting the addressed memory page 112 (e.g., activating one or more selection logic, circuitry, and/or gates within the memory core 111), configuring interconnection logic of the memory core 111 to couple the addressed memory page 112 to the read/write logic 140, generating select signals configured to couple the addressed memory page 112 to the read/write logic 140, routing memory signals 129 to and/or from the addressed memory page 112, configuring routing circuitry of the memory core 111 to route memory signals 129 to and/or from the addressed memory page 112, configuring interconnect logic of the memory core 111 to couple the memory page 112 to the read/write logic 140, selecting one or more columns and/or rows within a memory array (e.g., by use of an address decoder, a column decoder, a row decoder, and/or the like), and/or the like. In some embodiments, the memory pages 112 of the memory core 111 are embodied within a memory array, such as a two-dimensional memory array, a three-dimensional memory array, and/or the like; addressing the memory page 112 may comprise selecting the addressed memory page 112 within the memory array by use of one or more interconnect lines coupled to addressed memory page(s) 112.

In the FIG. 1C embodiment, the memory structure 110 comprises interconnect circuitry 113, which may be used to address selected memory pages 112 as disclosed herein. The address logic 130 may configure the interconnect circuitry 113 to address selected memory pages 112, as disclosed herein. The interconnect circuitry 113 may include, but is not limited to: selection logic, select gates, select lines, interconnection logic, interconnection gates, interconnection lines, routing logic, routing gates, routing lines, address lines, column lines, row lines, depth lines, select lines, select gate lines, data select lines, block select lines, page select lines, word select lines, cell select lines, read select lines, write select lines, sense select lines, vias, inter-layer vias, through-silicon vias, and/or the like.

The address logic 130 may leverage the interconnect circuitry 113 to address particular memory page(s) 112 within the memory structure 110. In some embodiments, the address logic 130 comprises address circuitry 134, which may be configured to generate addressing signals 139 to configure the interconnect circuitry 113 to address the particular memory page(s) 112. The addressing signals 139 may be configured to couple addressed memory page(s) 112 to the read/write logic 140, route memory signals 129 to and/or from the addressed memory page(s) 112, and so on. The address circuitry 134 may comprise circuitry configured to address memory page(s) 112 within the memory core 111 and/or configure the interconnect circuitry 113. Such circuitry may include, but is not limited to: address decoder circuitry, array addressing circuitry, two-dimensional array addressing circuitry (e.g., column decode circuitry, row decode circuitry, and/or the like), three-dimensional array addressing circuitry (e.g., column decode circuitry, row decode circuitry, depth decoder circuitry, and/or the like), select circuitry, gate select circuitry, interconnect control circuitry, signal routing circuitry, driver circuitry, and/or the like.

The read/write logic 140 may be configured to perform memory operations on addressed memory pages 112 of the memory structure 110. Such memory operations (OP) may include, but are not limited to: write operations, program operations, read operations, erase operations, initialize operations, reset operations, test operations, and so on. The read/write logic 140 may be configured to perform memory operations in response to a memory command 168. As disclosed in further detail herein, memory commands 168 may direct the memory logic 120 to perform specified memory operations on memory page(s) 112 of the memory structure 110. The read/write logic 140 may be configured to implement particular memory operations by, inter alia, communicating memory signals 129 to and/or from memory page(s) 112 addressed by the address logic 130. The read/write logic 140 may be configured to generate memory signals 129 configured to implement particular memory operations on the addressed memory page(s) 112, and may sense memory signals 129 produced by and/or returned from the addressed memory page(s) 112.

In the embodiments illustrated in FIG. 1C, the read/write logic 140 may implement memory operations (OP) by use of read/write circuitry 142. The read/write circuitry 142 may include, but is not limited to one or more of a: read circuit, write circuit, erase circuit, read/write circuit, program circuit, drive circuit, bias circuit, sense circuit, sense amplifier circuit, current sense circuit, voltage sense circuit, and/or the like. The read/write logic 140 may use the read/write circuitry 142 to perform memory operations on addressed memory pages 112 by, inter alia, configuring the read/write circuitry 142 to generate and/or sense memory signals 129. The read/write logic 140 use the read/write circuitry 142 to generate memory signals 129, which may be configured to perform particular memory operations on the memory page(s) 112 being addressed by the address logic 130. As disclosed above, the memory signals 129 generated by the read/write circuitry 142 may include, but are not limited to: read signals, read pulses, read bias signals, write signals, write pulses, write bias signals, program signals, program pulses, program bias signals, sense bias signals, and/or the like. The memory signals 129 depicted in FIG. 1C may comprise signals produced by and/or returned from the addressed memory page(s) 112. Such memory signals 129 may include, but are not limited to: signals produced by the addressed memory page(s) 112, signals returned from the addressed memory page(s) 112, signals responsive to memory signals 129 generated by the read/write circuitry 142 (e.g., a sense signal responsive to read and/or bias memory signals 129 produced by the read/write circuitry 142), and/or the like.

The address logic 130 may be configured to couple the read/write circuitry 142 to the addressed memory page(s) 112 such that: memory signals 129 generated by the read/write circuitry 142 are communicated to the addressed memory page(s) 112; memory signals 129 produced by and/or returned from the addressed memory page(s) 112 are communicated to the read/write circuitry 142 (e.g., sensed at the read/write circuitry 142); and so on. Similarly, the address logic 130 may be configured to: route memory signals 129 to the addressed memory pages 112, route memory signals 129 produced by and/or returned from the addressed memory page(s) 112 to the read/write circuitry 142, and so on. The address logic 130 may be configured to couple read/write circuitry 142 to the addressed memory page(s) 112, and/or route memory signals 129 therebetween, by use of the interconnect logic 113, and so on, as disclosed herein.

As disclosed above, the address logic 130 may be configured to address memory page(s) 112 within the memory structure 110. In some embodiments, the addressed memory page(s) 112 correspond to respective internal addresses 117. The internal addresses 117 may be defined by and/or correspond to an architecture and/or addressing scheme of the memory structure 110, memory core 111, and/or interconnect circuitry 113. In one embodiment, the memory structure 110 may comprise N memory pages 112, and may provide for naming, referencing, and/or addressing the memory pages 112 by use of a set of identifiers (e.g., 0 through N-1). A “first” memory page of the memory structure 110 may be named, referenced, and/or addressed as memory page 112 “0” and a “last” memory page 112 within the memory structure 110 may be designated as memory page 112 “N-1.” The interconnect circuitry 113 may provide for accessing the memory pages 112 by use of corresponding addressing signals 139; the memory pages 112 may be addressed by use of addressing signals 139 corresponding to the respective names, references, and/or identifiers of the memory pages 112 (e.g., 0 through N-1). The names, references, addresses, and/or addressing signals 139 used to address the memory pages 112 of the memory structure 110 may be referred to as “internal addresses” 117 of the memory structure 110. The set, range, and/or extent of the internal addresses 117 may be referred to as an “internal address space” 115 of the memory structure 110. In the example above, the internal memory address space 115 may comprise a set, range, and/or extent of internal addresses 0 through N-1. The internal addresses 117 may be referred to as “physical addresses,” “media addresses,” “memory core addresses,” “memory block address,” and/or the like.

Although particular internal addresses 117 and/or internal memory address space 115 are described herein, the disclosure is not limited in this regard and could be adapted to name, reference, and/or address memory pages 112 using any suitable addressing scheme. The internal addresses 117 and/or internal memory address space 115 disclosed herein may be adapted corresponding to the memory structure 110, architecture of the memory structure 110, substructures of the memory structure 110, and so on. In some embodiments, and as disclosed in further detail herein, the memory structure 110 may comprise a plurality of different sections. As used herein, a “section” of the memory structure 110 refers to a grouping and/or arrangement of memory pages 112 within the memory structure 110. A section of the memory structure 110 may correspond to one or more of: a memory architecture and/or layout of the memory pages 112 within the memory structure 110 and/or memory core 111, substructures (e.g., a plane, a memory plane, an array, a memory array, or the like), a substrate, a semiconductor, a semiconductor region, an architecture and/or addressing scheme implemented by the interconnect circuitry 113 of the memory structure 110, groupings of memory pages 112 (e.g., erase blocks), and/or the like. In some embodiments, sections of the memory structure 110 may be capable of parallel and/or concurrent operation, in which an operation on a first memory page 112 within a first section of the memory structure 110 is performed in parallel and/or concurrently with an operation on a second memory page 12 within a second section of the memory structure 110. The interconnect circuitry 113 may provide for addressing memory pages 112 within the different sections of the memory structure 110. In one embodiment, the memory structure 110 may comprise N memory pages 112, which may be evenly distributed between two different sections (section 0 and section 1). The interconnect circuitry 113 may provide for addressing memory pages 112 within the sections by use of internal addresses 117 ranging from 0 through N-1. The internal memory address space 115 of the memory structure 110 may, therefore, comprise two disjoint ranges 0 through N/2-1, and the corresponding internal addresses 117 may correspond to a specified one of the ranges (e.g., section 0 or section 1). Alternatively, the internal memory address space 115 may comprise a combined address space ranging from 0 through N-1. The interconnect circuitry 113 may address memory pages 112 within the different sections according to a particular addressing scheme (e.g., internal addresses 117 0 through N/2-1 may address memory pages 112 0 through N/2 within section 0, and internal addresses 117 N/2 through N-1 may address memory pages 112 within section 1).

Referring back to FIG. 1C, the address logic 130 may be configured to addresses memory pages 112 by use of internal addresses 117 of an internal memory address space 115 of the memory structure 110. As disclosed above, the internal addresses 117 may correspond to an architecture and/or layout of the memory structure 110, memory core 111, and/or the like. Alternatively, or in addition, the internal memory address space 115 may correspond to the interconnect circuitry 113 of the memory structure 110 (e.g., may correspond to addressing signals 139 used to address the memory pages 112 of the memory structure 110).

Referring to FIG. 1C, as disclosed above, the address logic 130 may be configured to address the memory pages 112 by use of internal addresses 117 (and/or corresponding addressing signals 139). The internal addresses 117 may correspond to an addressing scheme and/or addressing architecture of the memory structure 110, memory core 111, interconnect circuitry 113, and/or the like, as disclosed above. The memory structure 110 of FIG. 1C may comprise N memory pages 112, each of which may be addressable by use of internal addresses 117 (e.g., by use of the interconnect circuitry 113, address logic 130, and/or addressing signals 139, as disclosed herein). The internal addresses 117 may correspond to an internal memory address space 115, which may comprise a set, range, and/or extent of internal addresses 117 (e.g., 0 through N-1). The disclosure is not limited in this regard, and could be adapted to use any suitable set, group, collection, range, and/or extent of internal addresses 117 corresponding to any suitable internal memory address space 115 (e.g., a plurality of non-contiguous sets, ranges, and/or extents of internal addresses 117).

Although not depicted in FIG. 1C to avoid obscuring the details of the illustrated embodiments, the memory structure 110 may comprise one or more reserve memory pages. The reserve memory pages may not be made available for performing memory operations responsive to memory commands 168 from the controller 106 and/or host 103. The reserve memory pages may instead be reserved for other purposes, which may include, but are not limited to: reserve write capacity, to replace memory pages 112 that are no longer deemed to be suitable for use (e.g., have been taken out of service), storage of configuration data, maintaining status information pertaining to the memory structure 110, error logging, address translation metadata, error detection and/or correction information, and so on.

As disclosed above, the internal memory address space 115 of the memory structure 110 may span the addressable memory pages 112, such that each addressable memory page 112 available with the memory structure 110 is addressable through a respective internal address 117. Accordingly, in some embodiments, the internal memory address space 115 may indicate an available memory capacity of the memory structure 110. In the FIG. 1C embodiment, the internal memory address space 115 may comprise an range of internal addresses 117 from 0 through N-1, where N is the number of addressable memory pages 112 available within the memory structure 110. The available memory capacity of the memory structure 110 may, therefore, be expressed as N*EMC, where N is the number of addressable memory pages 112 (e.g., the size of the internal memory address space 115) and EMC is the effective memory capacity (EMC) of the respective memory pages 112. As used herein, the EMC of a memory page 112 refers to the amount of data each memory page 112 is configured to store (e.g., a size of the data area of the respective memory pages 112). Accordingly, the EMC of the memory pages 112 may be referred to as a “page size,” “block size,” “segment size,” or “sector size” of the memory pages 112. The memory pages 112 may be configured to store any suitable amount of data (e.g., 512 bytes, 4 kb, 16 kb, or the like). In some embodiments, the EMC of the memory pages 112 may be less than an full physical capacity of the memory pages 112; each memory page 112 may include a data area and a spare area for storing auxiliary data. Auxiliary data may include, but is not limited to: metadata, status information, error detection and/or correction data (e.g., error-correction code (ECC) information, an ECC syndrome, an ECC symbol, a hash of the data unit, a signature of the data unit, or the like), data redundancy information, and so on. In some embodiments, the memory logic 120 and/or controller 106 may encode data for storage within the memory system 101. Encoding data units may result in increasing the size thereof. An encoded data unit may extend beyond the first portion of a memory page 112, and may consume at least some of the second portion of the memory page 112 (e.g., extend into the auxiliary area of the memory page 112).

As illustrated in FIG. 1C, both the memory logic 120 and the memory core 111 may be embodied within the memory structure 110. As such, the memory logic 120 may be embodied on the same chip, package, die, substrate, semiconductor substrate, NAND-Flash die, NOR-Flash die, and/or other memory structure 110 as the memory core 111 (and memory pages 112). In some embodiments, the memory structure 110 may comprise a plurality of substrates (e.g., stacked substrates), and the memory logic 120 may be embodied on one or more of the plurality of substrates. The disclosure is not limited in this regard; in some embodiments, the memory logic 120 may be embodied separately from the memory structure 110 and/or memory core 111 and/or may be embodied within a separate substructure or region of the memory structure 110. The memory logic 120 may, for example, be embodied on a chip, package, die, substrate, semiconductor device, and/or other structure, which may be separate from the corresponding structures and/or substructures embodying the memory core 111.

The controller 106 may receive commands 104 pertaining to the memory system 101 via the interconnect 105. The commands 104 may comprise commands to write data to the memory system 101, read data from the memory system 101, request status information pertaining to the memory system 101, access configuration information pertaining to the memory system 101, configure the memory system 101, and so on. The controller 106 may implement commands 104 by use of the memory structure 110, and may provide corresponding responses thereto. Implementing a command 104 may comprise issuing one or more memory commands 168 to the memory logic 120. The memory commands 168 may direct the memory logic 120 to perform memory operations on specified memory pages 112 of the memory core 111. Memory commands 168 may be configured to, inter alia, instruct the memory logic 120 to perform specified operations (OP) pertaining to the memory structure 110, and may include, but are not limited to: parameters, flags, data, opcodes, configuration information, and/or the like.

The memory logic 120 may receive memory commands 168 from the controller through a memory core interconnect 107 of the memory system 101. The memory core interconnect 107 may be configured to communicatively couple the controller 106 to the memory structure 110 (e.g., the memory logic 120). The memory core interconnect 107 may comprise any suitable interconnect structures including, but not limited to: a bus, a parallel bus, a serial bus, and/or the like. Therefore, although not depicted in FIG. 1C to avoid obscuring the details of the illustrated embodiments, the controller 106 and/or memory logic 120 may comprise respective interface components coupled to the memory core interconnect 107. The controller 106 may, for example, generate clock and/or timing signal(s) for use within the memory core 111 and/or for use for communication via the memory core interconnect 107.

The memory logic 120 may implement memory commands 168 by, inter alia, a) addressing memory pages 112 corresponding to the addressee (AD) specified in the memory commands 168 (e.g., by use of the address logic 130), and b) performing one or more memory operation(s) on the addressed memory pages 112 (e.g., by use of the read/write logic 140). In some embodiments, the memory logic 120 implements a memory command 168 to write data to the memory system 101 by, inter alia: a) addressing a memory page 112 corresponding to the memory command 168 (e.g., memory page 112A), and b) performing write operation(s) on the addressed memory page 112A. The write operation(s) may comprise programming data on the addressed memory page 112A (e.g., by applying a sequence of program pulses to the addressed memory page 112A). The write operation(s) may further comprise writing auxiliary data on the addressed memory page 112A, such as metadata, error detection and/or correction data, and so on. In some embodiments, the write operation(s) may further comprise verifying that the data was successfully written to the addressed memory page 112A, which may comprise detecting write errors, verifying data stored on the addressed memory page 112 (e.g., by reading data from the addressed memory page 112A and/or verifying the error-detection and/or correction information thereof), and so on.

The memory logic 120 may execute a memory command 168 to read data from the memory system 101 by, inter alia, a) addressing a memory page 112 corresponding to the memory command 168 (e.g., storage unit 112A), and b) performing read operation(s) on the addressed memory page 112A. The read operation(s) may comprise verifying data read from the addressed memory page 112A by, inter alia, detecting read errors, accessing error correction and/or detection written to the memory page 112A, correcting errors detected in the data (if any), reporting uncorrectable errors detected in the data (if any), and so on.

The memory logic 120 may be configured to provide responses to memory commands 168 through the memory core interconnect 107. A response to a memory command 168 may include, but is not limited to: an acknowledgement of successful completion of the memory command 168, an indication that the memory command 168 failed, a failure code, an indication of partial completion of the memory command 168 (e.g., the command completed with errors), an error code, a status code, an interrupt signal, and/or the like. A response to a memory command 168 may further comprise data read from one or more memory pages 112, status information pertaining to the memory structure 110, configuration information pertaining to the memory logic 120, and so on.

A memory command 168 to read data from the memory core 111 may fail due to various reasons including, but not limited to: a hardware fault, an addressing fault (e.g., a fault in selection, interconnect, and/or routing logic of the memory core 111 and/or interconnect circuitry 113), read sense errors, bit errors, uncorrectable bit errors, verification failures (e.g., ECC decode errors, signature mismatch), and/or the like. Read failures may result in data loss or corruption.

In some embodiments, data may be protected from loss and/or corruption by use of, inter alia, external data protection components (not shown in FIG. 1C to avoid obscuring the details of the illustrated embodiments). Although external data protection components may be capable of recovering from failure conditions at both the storage location and device level, such components can impose substantial overhead and complexity. The memory system 101 disclosed herein may be configured to implement highly-available memory operations within the memory structure 110 itself, and without the need for external data protection components. The memory system 101 disclosed herein may be configured to protect data units from loss and/or corruption by, inter alia, storing data units within two (or more) memory pages 112 of the memory core 111. Accordingly, data may be protected from loss and/or corruption within the memory structure 110 itself, and without the need of any external data protection components. In some embodiments, data units are protected from loss and/or corruption by use of a “high-availability” memory die (e.g., NAND-Flash die), which may be configured to redundantly store data units written thereto on two or more different storage units 112A. In some embodiments, the disclosed memory system 101 may be configured to provide highly-available memory services within the memory structure 110, independently of the controller 106, the host 103 and/or other systems, devices, processes, components, elements, logic, and/or external to the memory structure 110. Accordingly, in some embodiments, the memory structure 110 is configured to protect data units from loss and/or corruption independently of, and without the need for, any external data protection components.

As disclosed above, the memory system 101 may be configured to provide highly-available memory services within the memory structure 110 (e.g., by use of the memory core 111 and corresponding memory logic 120). Providing highly-available memory services may comprise protecting data stored within the memory structure 110 from loss and/or corruption by, inter alia, storing redundant copies of data within the memory core 111. In the FIG. 1C embodiment, the memory logic 120 may be configured to provide highly-available memory services by, inter alia, a) implementing memory commands 168 to store data units within the memory structure 110 by writing respective data units to two (or more) different memory pages 112, such that each data unit is stored redundantly on two or more memory pages 112 within the memory structure 110, and b) implementing memory commands 168 to read data units stored within the memory structure 110 by use of the two or more memory pages 112 comprising the respective data units. Implementing a memory command 168 to read a data unit from the memory structure 110 may comprise performing first read operation(s) on a first memory page 112 within the memory structure 110, and performing second read operation(s) on a second memory page 112 to prevent data loss or corruption (e.g., responsive to a read failure, bit errors, uncorrectable bit errors, data verification failure, and/or the like). Alternatively, implementing the memory command 168 to read the data unit from the memory structure 110 may comprise performing the first and second read operation(s) regardless of failure and/or error conditions pertaining to the first and/or second read operation(s). In some embodiments, the first and second read operation(s) may be performed within separate sections of the memory core 111 (e.g., within separate memory arrays, memory planes, and/or the like), which may enable the first and second read operation(s) to be performed in parallel, simultaneously, and/or concurrently.

Memory commands 168 directed to the memory structure 110 may be configured to, inter alia, instruct the memory logic 120 to perform particular operations within the memory core, such as operations to store a data unit within the memory structure 110, read a data unit from the memory structure 110, and so on. The memory commands 168 may specify an operation to perform by use of a command parameter, op code, flag, or the like. The exemplary memory command 168 depicted in FIG. 1C includes an (OP) parameter, which may be configured to direct the memory logic 120 to perform one or more operation(s). In some embodiments, the memory command 168 may include memory addressing information, which may specify memory addresses to which the indicated operation(s) pertain (e.g., specify memory addresses to which data is to be written, programmed, read, or the like). The exemplary memory command 168 depicted in FIG. 1C comprises an external address 137. The memory logic 120 may implement the memory command 168 by: a) addressing the memory page 112 associated with the specific external address 137 (by use of the address logic 130), and b) performing the specified operation(s) on the addressed memory page 112, as disclosed herein. As used herein, an external address 137 refers to any data, signal, and/or value configured to reference data pertaining to the memory structure 110 (e.g., a data unit). In some embodiments, external addresses 137 may correspond to data blocks, segments, or the like. The memory logic 120 may represent that the memory 102 is capable of storing N data blocks or pages. The external addresses 137 may comprise block and/or page numbers. The external addresses 137 may correspond to an external memory address space 135 for the memory structure 110 (e.g., a range of block or page addresses). The external memory address space 135 may be configured to enable entities external to the memory structure 110, such as the controller 106, host 103, or the like, to reference data units being written to and/or retrieved from the memory structure 110. As such, the external addresses 137 of the external memory address space 135 may be referred to as “data addresses,” “page addresses,” “data segment addresses,” “external addresses” 137 or the like.

In some embodiments, the external memory address space 135 corresponds to the internal memory address space 115 of the memory 102. As disclosed above, the internal memory address space 115 may comprise a set, range, and/or extent of internal addresses 117, each of which may be used to address a respective memory page 112 by the address logic 130. In the FIG. 1C embodiment, the internal memory address space 115 may comprise N internal addresses 117 (0 through N-1), where N is the number of addressable memory pages 112 available within the memory structure 110. The external memory address space 135 may comprise a corresponding range of data blocks and/or pages (e.g., 0 through N-1). In some embodiments, the external memory address space 135 corresponds to the internal memory address space 115, such that each external address 137 of the external memory address space 135 corresponds to a respective internal address 117 of the internal memory address space 115. The external memory address space 135 may comprise the same set, range, and/or extent as the internal memory address space 115 (e.g., the external memory address space 135 may comprise addresses ranging from 0 through N-1, where N is the number of addressable memory pages 112 available within the memory structure 110). In such embodiments, the address logic 130 may perform one-to-one addressing between the external memory address space 135 and the internal memory address space 115 (and corresponding memory pages 112). Accordingly, each external address 137 of the external memory address space 135 may address a respective memory page 112 within the memory structure 110 (through a respective internal address 117).

As disclosed above, the controller 106 may issue memory commands 168 which may be configured to direct the memory logic 120 to perform specified memory operations (OP) within the memory 102. The memory commands 168 may direct the memory logic 120 to perform operation(s) in reference to particular locations within the memory. The memory commands 168 may comprise address information, which may direct the memory logic 120 to perform the specified operations (OP) on particular locations within the memory 102 (e.g., on particular memory pages 112). The addressing information of the memory commands 168 of FIG. 1C may comprise external address(es) 137 of an external memory address space 135 corresponding to the memory structure 110. The address logic 130 may be configured to translate and/or convert external addresses 137 of the memory commands 168 (e.g., data segment address, page address, and/or the like) to determine corresponding internal addresses 117 (e.g., physical address, media addresses, and/or the like). The address logic 130 may be further configured to generate addressing signals 139, route signals to/from addressed memory pages 112, and so on.

In some embodiments, the address logic 130 comprises translation circuitry 132, which may be configured to implement translations between external addresses 137 (and/or other address information of a memory command 168) to one or more internal addresses 117 (and/or addressing signals 139). The translation circuitry 132 may comprise logic configured to perform address translations between external addresses 137 and internal addresses 117 (and/or corresponding addressing signals 139 to address particular memory pages 112). The translation circuitry 132 may comprise any suitable structure for generating one (or more) internal addresses 117 and/or addressing signals 139 responsive to addressing information (e.g., a memory command 168, external address 137, and/or the like). The translation circuitry 132 may be configured to perform any suitable address translation operations, which may include, but are not limited to: offset operations, shift operations, range shift operations, modulo operations, lookup operations, and/or the like. The translation circuitry 132 may include, but is not limited to: translation circuitry, lookup table circuitry, address table circuitry, address translation circuitry, arithmetic logic circuitry, and/or the like. Although the translation circuitry 132 of FIG. 1C is described in relation to external addresses 137 (internal addresses 117), the disclosure is not limited in this regard; the address logic 130 and/or translation circuitry 132 could be adapted for use with any type of addressing information, including, but not limited to: memory commands 168, block identifiers, block numbers, offsets, block addresses, memory addresses, and/or the like. The address logic 130 and/or translation circuitry 132 may be further adapted to generate internal addresses 117 and/or addressing signals 139 of any suitable type and for use with any type of interconnect circuitry 113.

Diagram 131A depicts one embodiment of address translations implemented by the address logic 130 (and/or translation circuitry 132). The translations depicted in diagram 131A may comprise one-to-one translations between external addresses 137 and internal addresses 117, such that each external address 137 corresponds to a respective internal address 117 of a memory page 112 (and vice versa). As illustrated in diagram 131A, the address logic 130 may use the internal address 117 translated 132 from the external address 137 to address a memory page 112 within the memory structure 110 (e.g., memory page 112A), as disclosed herein.

In some embodiments, the address logic 130 may configure the external memory address space 135 to include the same range and/or extent of addresses as the internal memory address space 115. In such embodiments, the address logic 130 may implement “direct” translations between external addresses 137 and internal address 117 (e.g., the address logic 130 may use external addresses 137 as internal addresses 117 to directly address corresponding memory pages 112, without translation by the translation circuitry 132). For example, the external memory address space 135 may have external addresses 137 ranging from 0 through N-1, which may directly correspond to internal addresses 117 0 through N-1 of the internal memory address space 115. Although specific examples of address translations are disclosed herein, the disclosure is not limited in this regard. In other embodiments, address logic 130 may configure the external memory address space 135 to include a different set, range, and/or extent than that of the internal address space 117.

In some embodiments, the memory logic 120 is configured to publish addressing information pertaining to the memory structure 110. As used herein, “publishing” addressing information may include, but is not limited to: publishing addressing information on the memory core interconnect 107, registering a particular set, range and/or extent of addresses corresponding to the interconnect, pushing addressing information to the controller 106, transmitting addressing information to the controller 106, updating configuration and/or status information pertaining to the memory structure 110, responding to memory commands 168 pertaining to the addressing information (e.g., memory commands 168 pertaining to a configuration and/or status of the memory logic 120), and so on. Publishing address information may comprise publishing the external memory address space 135 of the memory structure 110, which may include providing metadata indicating the set, range, and/or extent of external addresses 137 that are available within the memory 102 (e.g., publish the external memory address space 135). Alternatively, or in addition, publishing address information may comprise publishing an indication of a size, range, and/or extent of blocks and/or memory pages 112 available within the memory 102. When the address logic 130 is configured to implement one-to-one translations between external addresses 137 and memory pages 112, the size, range and/or extent of the external memory address space 135 may be N, where N is the number of addressable memory pages 112 available within the memory structure 110. The controller 106, or other external entity, may derive external addresses 137 from the indicated size (e.g., external addresses 137 from 0 through N-1, as disclosed herein).

Publishing addressing information may further include providing a “published memory capacity” for the memory structure 110. As used herein, the “published memory capacity” or “external memory capacity” of the memory structure 110 refers to the amount of memory capacity capable of being referenced through the external memory address space 135. The published memory capacity may be expressed as N_E*EMC, where N_E is the number of external addresses 137 within the external memory address space 135 (e.g., the size, range, and/or extent of the external memory address space 135), and EMC is the effective memory capacity of each memory page 112, as disclosed above. In embodiments where the external memory address space 135 is coextensive with the internal memory address space 115, the published memory capacity may be equivalent to the internal memory capacity of the memory structure 110, disclosed above.

To provide highly-available memory services within the memory structure 110, the address logic 130 may be configured to implement a different address translation scheme between external addresses 137 and memory pages 112 (e.g., internal addresses 117). When configured to implement highly-available memory operations, the address logic 130 may be configured to address two (or more) different memory pages 112 responsive to respective external addresses 137. When so configured, the translation circuitry 132 may implement a one-to-many translation scheme between the external and internal address space 135 and 115 in which each external address 137 corresponds to two (or more) different internal addresses 117.

In some embodiments, when the memory logic 120 is configured for HA operation, the address logic 130 may be configured to: a) modify the external memory address space 135, and/or b) implement one-to-many address translations between external addresses 137 of the external memory address space 135 by use of the translation circuitry 132. Modifying the external memory address space 135 may comprise modifying the number of memory pages (e.g., memory blocks and/or units represented as being available and/or addressable within the memory 102. For example, when configured for non-HA operation, the address logic 130 may implement one-to-one translations between external addresses and memory pages 112. Accordingly, the memory logic 120 may represent that the memory 102 comprises N memory blocks and/or memory pages 112 (e.g., the external memory address space 135 may comprise N external addresses from 0 through N-1). When configured for HA operation in which each block is written to M memory pages 112 within the memory core 111 (where M is two or more), the address logic 130 may be configured to map each block to M memory pages 112 (as opposed to only one memory page 112). As such, when configured for HA operation, the memory logic 120 may represent that the memory 102 comprises N/M external addresses 137 in accordance with the one-to-M relationship between external addresses 137 and memory pages 112. As such, implementing HA memory operations may comprise notifying the controller 106 of corresponding changes to the number of memory pages 112 and/or blocks available within the memory structure 110. Modifying the external memory address space 135 may comprise adjusting the size, range, and/or extent of the external memory address space 135 in accordance with a relationship between the external addresses 137 and the memory pages 112. As disclosed above, implementing HA memory operations may comprise writing respective data units to M different memory pages 112, where M is two or more. To implement such operations, the address logic 130 may be configured to translate and/or convert each external address 137 to M internal addresses 117 (which in turn address M memory pages 112). The address logic 130 may, in some embodiments, be configured to reduce a size, range, and/or extent of the external address space by M, such that a size, range, and/or extent of the external memory address space 135 is modified to be N/M (rather than N as in a one-to-one addressing embodiment).

Diagram 131B depicts embodiments for one-to-M translations, wherein each external address 137 corresponds to a respective set of M memory pages 112 of the memory 102. In diagram 131B, M is two, such that each external address 137 corresponds to two memory pages 112 (through respective internal addresses 117 and/or address signals 139). As illustrated, the size of the external memory address space 135 may be reduced by M, to include N/M unique external addresses 137 (e.g., N/2 external addresses 137). The translation circuitry 132 may be configured to translate and/or convert each external address 137 to a set of two internal addresses 117, including a first address 117A and a second address 117B. Therefore, in response to being configured to implement M-way data redundancy, the address logic 130 may be configured to: a) modify the translation circuitry 132 to implement a one-to-M address translation scheme, and b) address M memory pages 112 responsive to external addresses 137. Modifying the number, range, and/or extent of external addresses 137 corresponding to the memory 102 (e.g., representing that the memory 102 comprises N/M blocks and/or memory pages 112 as opposed to N). Modifying the external memory address space 135 may comprise notifying the controller 106 that the memory 102 comprises 1/M of a full storage capacity thereof. When configured for M-way redundancy, the address logic 130 may modify the external memory address space 135, such that the published storage capacity of the memory 102 is N * EMC/M, where N is the number of addressable memory pages 112 available within the memory core 111, and EMC is the effective memory capacity of each memory page 112 (e.g., a size of the data area of the memory pages 112).

As disclosed above, implementing highly-available memory operations may comprise writing data on two different memory pages 112 of the memory structure 110. When configured to implement highly-available memory operations, the memory logic 120 may implement a memory command 168 to write a data unit (D4) to a designated external address 137 by, inter alia: a) using the translation circuitry 132 to translate and/or convert the external address 137 to two different internal addresses 117 (e.g., internal addresses 117A and 117B), b) using the address logic 130 to address corresponding memory pages 112A and 112B, and c) using the read/write logic 140 to implement write operation(s) to store the data segment (D4) on both of the addressed memory pages 112A and 112B. The read/write logic 140 may be configured to write the data unit (D4) to both of the addressed memory pages 112A and 112B. In some embodiments, the read/write logic 140 is configured to perform first write operation(s) to store the data segment (D4) on memory page 112A, and second write operation(s) to store the data segment (D4) on memory page 112B. The read/write logic 140 may be configured to perform the first and the second write operation(s) in accordance with different degrees of parallelism and/or concurrency, such that: the first and second write operation(s) are performed substantially in parallel, are performed concurrently, are partially concurrent (partially overlapping in time), are performed non-concurrently (e.g., non-overlapping in time), are performed sequentially (e.g., according to a particular order), and/or the like. Alternatively, or in addition, the read/write logic 140 may be configured to write the data unit (D4) to the addressed memory pages 112A and 112B in the same write operation(s). The write operation(s) may comprise generating memory signals 129 configured to program the data unit (D4) on the addressed memory pages 112A and 112B. As disclosed above, the memory signals 129 may include, but are not limited to: program pulses, write pulses, bias signals, bias pulses, and/or the like. The address logic 130 may be configured to couple the write logic 140 to the addressed memory pages 112A and 112B and/or route the memory signals 129 thereto, as disclosed herein. The write operation(s) may further comprise writing error correction and/or detection information corresponding to the data unit (D4) on the addressed memory pages 112A and 112B (in auxiliary space of the memory pages 112A and 112B), verifying that the data unit (D4) was successfully written to the memory pages 112A and 112B, and so on.

The memory logic 120 may provide a response to the memory command 168 to write data (D4) to the memory 102, which may comprise one or more of: acknowledging successful completion of the memory command 168 responsive to verifying that the data unit (D4) was successfully stored within both memory pages 112A and 112B, returning an indication that the memory command 168 was partially completed responsive to successfully writing the data unit (D4) to only one of the addressed memory pages 112A or 112B, returning an indication that one or more of the write operation(s) failed, returning an indication that the data unit (D4) could not be written to either memory page 112A or 112B, an indication of whether the data is protected from loss and/or corruption (e.g., whether the data unit (D4) was successfully written to both memory pages 112A and 112B), and/or the like.

Implementing highly-available memory operations may comprise servicing requests to read data stored redundantly within two or more memory pages 112 of the memory structure 110. The memory logic 120 may be configured to implement a memory command 168 to read data stored at the external address 137 to which data (D4) was written by, inter alia: a) using the translation circuitry 132 to generate internal addresses 117A and 117B responsive to the external address 137, b) using the address logic 130 to address one or more of the memory pages 112A and 112B, and c) performing read operation(s) on one or more of the memory pages 112A and 112B. The read operation(s) may comprise sensing data stored within one or more of the memory pages 112A and 112B. The read operation(s) may further comprise verifying data read from the one or more memory pages 112A and 112B (by use of error detection and/or correction stored within the memory pages 112A and/or 112B), and so on. In some embodiments, the read/write logic 140 is configured to perform first read operation(s) on a first one of the addressed memory pages 112A or 112B. In response to a failure of the first read operation(s), the memory logic 120 may perform second read operation(s) on a second one of the memory pages 112A or 112B. The memory logic 120 may not perform the second read operation(s) if the first read operation(s) are completed successfully. Alternatively, the read/write logic 140 may be configured to perform read operation(s) on both memory pages 112A and 112B. The read operation(s) may comprise separate read operation(s) on the respective memory pages 112A and 112B, which may be performed in parallel, concurrently, partially concurrently, non-concurrently, and/or sequentially, as disclosed herein. Alternatively, the read operation(s) may comprise a same set of read operation(s) performed on both of the memory pages 112A and 112B. The memory logic 120 may verify data read from the memory page(s) 112A and/or 112B and may provide a response to the memory command 168, as disclosed herein. The response may comprise data read from one or more of the memory pages 112A and 112B, an indication that the read operations were completed successfully, an indication of a read failure and/or read errors pertaining to one or more of the memory pages 112A and/or 112B, an indication of whether the data is still protected from loss and/or corruption (e.g., whether the data is retrievable from both memory pages 112A and 112B), and so on.

In some embodiments, the memory logic 120 may be configured to operate according to a selected operating mode 123. As used herein, an “operating mode” or “selected operating mode” 123, refers to configuration information that, inter alia, defines the manner in which the memory logic 120 implements particular memory operations. The operating mode 123 comprise a first operating mode in which the memory logic 120 is configured to implement non-HA memory operations, such that data is not protected from loss and/or corruption within the memory structure 110 by, inter alia, redundant storage on two or more different memory pages 112 of the memory 102. When the operating mode 123 configures the memory logic 120 to operate according to the first operating mode, the memory logic 120 may implement a write command to store a data block within the memory 102 by writing the data block to a single memory page 112, such that the data block is not afforded the additional protection from loss and/or corruption provided by redundant storage on two (or more) different memory pages 112 within the memory structure 110. The first mode may, therefore, comprise a standard, non-redundant, or non-HA mode. The memory logic 120 may be configured to operate according to other modes, including a second operating mode. The second operating mode may comprise a “high-availability”(HA) mode in which data are stored redundantly on two (or more) different locations within the memory 102 (e.g., two or more different sets of memory pages 112). The selected operating mode of the memory logic 120 may determine the manner in which memory commands 168 are implemented, such as, inter alia, the manner in which the address logic 130 addresses memory pages 112 responsive to external addresses 137 of the memory commands 168 (e.g., the number of memory pages 112 addressed by respective external addresses 137), the manner in which data units are programmed memory page(s) 112 (e.g., configuration of write operation(s) implemented by the read/write logic 140), and so on.

In some embodiments, the memory logic 120 comprises configuration logic 122, which may be adapted to cause the memory logic 120 to implement memory operations in accordance with a selected one of a plurality of operating modes (e.g., operating mode 123). As disclosed above, the operating mode 123 of the memory logic 120 may define, inter alia, the manner in which the memory logic 120 implements memory commands 168 to, inter alia, read data from the memory structure 110, write data to the memory structure 110, and so on. In response to a memory command 168, the configuration logic 122 may configure the memory logic 120 to perform a particular sequence of operation(s). The particular sequence of operation(s) may correspond to the operating mode 123, such that the particular sequence of operation(s) implemented by the memory logic 120 in response to a memory command 168 may differ based on the operating mode 123 of the memory logic 120. The configuration logic 122 may be configured to set the operating mode 123 of the memory logic 120 based on pre-determined configuration information (e.g., a default configuration and/or default settings for the memory structure 110 and/or memory system 101). The configuration logic 122 may be configured to report the operating mode 123 to one or more of the controller 106, host 103, and/or the like. In some embodiments, the memory system 101, controller 106, and/or memory logic 120 comprises an interface to query and/or set the configuration of the memory system 101, controller 106, and/or memory logic 120 (e.g., query and/or set the operating mode 123). In some embodiments, the operating mode 123 of the memory logic 120 may be queried and/or set through one or more of: interface commands (e.g., commands received through an interface of the memory system 101, controller 106, and/or memory logic 120), device commands (e.g., POKE commands, PEEK commands, set commands, get commands, setpci commands, hdparm commands, ioctl commands, and/or the like), memory commands 168 (e.g., configuration commands, memory command parameters, memory command flags, and/or the like), combinations of the foregoing, and/or any suitable mechanism for reporting and/or setting configuration information.

The configuration logic 122 may comprise and/or be communicatively coupled to persistent memory resources, which may include, but are not limited to: one or more registers, one or more memory pages 112 (e.g., reserved memory pages 112), firmware, an EEPROM, and/or the like. The configuration logic 122 may be configured to maintain metadata pertaining to the memory structure 110, memory core 111, and/or memory logic 120 (e.g., the selected operating mode of the memory logic 120), within the persistent memory resources. The configuration logic 122 comprises logic elements configured to determine, maintain, and/or update state information pertaining to operation(s) being performed by the memory logic 120; such information may include, but is not limited to: state information pertaining to write operation(s), state information pertaining to read operation(s), state information pertaining to erase and/or re-initialization operations, and so on. In some embodiments, the configuration logic 122 comprises state logic, a state circuit, a state machine, state machine logic, a state machine circuit, and/or the like.

The configuration logic 122 may cause the memory logic 120, including the read/write logic 140 and address logic 130, to implement memory operations in accordance with a selected operating mode, including a first mode and a second mode. When configured for operation in the first mode, the configuration logic 122 may cause the memory logic 120 to implement “non-redundant” memory operations, which may comprise writing data on respective memory pages 112, without storing the redundant copies of the data on other memory pages 112 within the memory structure 110. When configured for operation in the second mode, the configuration logic 122 may cause the memory logic 120 to implement HA memory operations, which may comprise writing two (or more) copies of data within different sets of memory pages 112 of the memory structure 110, as disclosed herein.

The selected operating mode may determine how the memory logic 120 responds to error and/or failure conditions. When configured for operation according to a “strict” HA mode, the memory logic 120 may acknowledge successful completion of a memory command 168 in response to determining that corresponding memory operations were successfully completed on each of the M memory pages 112 associated with the memory command 168. The memory logic 120 may indicate successful completion of the memory command 168 to write data segment (D4) in response to determining that the data segment (D4) was successfully written to both memory pages 112A and 112B. The memory logic 120 may return an indication that the memory command 168 failed responsive to determining that the data segment (D4) was not successfully stored within either memory page 112A or 112B. Similarly, when configured for operation in the “strict” HA mode, the memory logic 120 may verify that data being read from the memory 102 is available on each of M different memory pages 112. When so configured, the memory logic 120 may acknowledge successful completion of memory operations to read data (D4) in response to verifying that the data (D4) is retrievable from both memory pages 112A and 112B. The memory logic 120 may return an error code and/or interrupt responsive to detecting a read failure (and/or read errors) pertaining to either of the memory pages 112A or 112B. When configured for operation according to a “lax” HA mode, the memory logic 120 may be configured to acknowledge completion of memory commands 168 responsive to successful completion of corresponding memory operation(s) on any of the M memory pages.

The memory logic 120 may be further configured to manage error conditions in accordance with the selected operating mode thereof. When configured for operation in the “strict” HA mode, the memory logic 120 may be configured to replace memory pages 112 with reserve memory pages available within the memory core 111 responsive to detecting an error pertaining to any of the M memory pages 112 corresponding to a memory command 168. In response to a failure to write the data (D4) to memory page 112A or 112B, the memory logic 120 may replace the failed memory page 112A or 112B with a reserve memory page, such that the data (D4) is protected from loss and/or corruption. When configured for operation in the “strict” HA mode, the memory logic 120 may be configured to replace memory pages 112 responsive to read failures. The memory logic 120 may, for example, be configured to replace one of the memory pages 112A or 112B during implementation of a memory command 168 to read the data (D4) in response to detecting a read failure pertaining to the memory page 112A or 112B. Replacing the memory page 112A or 112B may comprise mapping a replacement memory page to the internal address 117 of the memory page 112A or 112B that is being replaced, and writing the data (D4) to the replacement memory page, such that the data (D4) continues to be protected from loss and/or corruption.

In other operating modes, such as the “lax” HA operating mode, the core memory 120 may be configured to replace memory pages 112 in response to detecting a failure of two (or more) of the M memory pages 112 corresponding to a memory command 168. In the “lax” HA operating mode, the memory logic 120 may replace one of the memory pages 112A or 112B with a reserve memory page responsive to determining that the data (D4) could not be stored within either memory page 112A or 112B. In the “lax” HA operating mode, the memory logic 120 may be configured to implement memory commands 168 to read data from the memory 102 by reading data from any of the M memory pages 112 corresponding to the memory commands 168 and without verifying that the data is retrievable from others of the M memory pages 112. In the “lax” HA operating mode, the memory logic 120 may not replace memory pages 112 with reserve memory pages responsive to read failures. The memory logic 120 may not, for example, replace memory page 112A responsive to a failure to retrieve data (D4) therefrom. The memory logic 120 may, however, be configured to respond to the corresponding memory command 168 with an indication that the data could only be read from one of the memory pages 112 and/or that the data (D4) is no longer being stored redundantly within the memory 102 (e.g., is not protected from loss and/or corruption within the memory 102). In other redundancy schemes, the memory logic 120 may be configured to replace memory pages 112 responsive to detecting read and/or write failures in more than a threshold number of M memory pages 112. In the “lax” HA mode, the memory logic 120 may replace one of M memory pages 112 corresponding to a particular external address 137 responsive to detecting read and/or write failures in two (or more) of the M memory pages 112.

The configuration logic 122 may be further adapted to direct the address logic 130 to modify the external memory address space 135, publish modifications to the external memory address space 135, and/or implement addressing schemes (by use of the translation circuitry 132) between the external memory address space 135 and memory pages 112 within the memory structure 110 in accordance with the selected operating mode. As disclosed herein, when configured for operation in the first mode, configuration logic 122 may cause the address logic 130 to perform one-to-one, or “direct,” translations between external addresses 137 and internal addresses 117 (and corresponding memory pages 112). In some embodiments, when configured for operation in the first mode, the configuration logic 122 directs the address logic 130 to publish the internal memory address space 115 to the controller 106 and/or publish an external memory address space 135 comprising the same set, range, and/or extent of addresses as the internal memory address space 115. When configured for operation in the second mode, the configuration logic 122 may direct the address logic 130 to modify the external memory address space 135 (e.g., reduce the size, range, and/or extent of the external memory address space 135, publish the modified external memory address space 135, and implement one-to-many translations between external addresses 137 and internal addresses 117 (and corresponding memory pages 112) by use of the translation circuitry 132.

FIG. 1D is a schematic block diagram of another embodiment of a memory system 101 configured to implement high-availability memory operations. In the FIG. 1D embodiment, the memory structure 110 comprises a memory substrate 160. The memory substrate 160 may include, but is not limited to: a package, a memory chip, a wafer, a semiconductor substrate, a memory die, a NAND-Flash memory die, a NOR-Flash memory die, and/or the like.

In the FIG. 1D embodiment, the memory substrate 160 comprises a plurality of sections 114, each of which may comprise a plurality of memory pages 112. The sections 114 may correspond to respective “failure domains” of the memory substrate 160. As used herein, a “failure domain” refers to a grouping of memory pages 112 that are subject to a particular set of failure modes and/or conditions. The memory pages 112 within section 114A of FIG. 1D may be affected by certain failure modes and/or conditions that do not affect the memory pages 112 within section 114B (and vice versa). The sections 114A and 114B may correspond to respective regions of the internal memory address space 115 of the memory substrate 160, respective memory arrays formed on the memory substrate 160, respective memory planes formed on the memory substrate 160, respective memory substrates, respective memory semiconductor regions, and/or the like. The sections 114A and 114B may comprise substantially equivalent amounts of memory pages 112. In the FIG. 1D embodiment, the memory substrate 160 comprises N memory pages 112, embodied within two different sections 114A and 114B. The sections 114A and 114B may comprise substantially equivalent numbers of memory pages 112 (e.g., each section 114A and 114B may comprise N/2 memory pages 112). Although not depicted in FIG. 1D to avoid obscuring the details of the illustrated embodiments, each section 114A and 114B may comprise reserve memory pages 112, as disclosed herein. In some embodiments, the sections 114A and 114B correspond to respective sets, ranges, and/or extents of core addresses 137; the memory pages 112 of the first section 114A may be addressable through a first internal memory address space 115A, which may comprise addresses ranging from 0 through N/2-1. The memory pages 112 of the second section 114B may be addressable through a second internal memory address space 115A, which may comprise a similar address range (e.g., 0 through N/2-1). The address logic 130 may publish an external memory address space 135, which, when configured for operation according to the first mode, may comprise external addresses 0 through N-1. The translation circuitry 132 may be further configured to selectively translate and/or convert external addresses 137 to memory pages 112 within the first section 114A or the second section 114B.

Diagram 131C depicts embodiments of non-redundant, one-to-one translations implemented by the address logic 130 (during operation according to the first mode). The sections 114A and 114B may each comprise N/2 memory pages 112, which may be addressable through respective internal address spaces 115A and 115B. The address logic 130 may configure the external memory address space 135 to span the internal address spaces 115A and 115B. Accordingly, the external memory address space 135 may comprise the range 0 through N-1. The address logic 130 may be configured to translate and/or convert the external memory address space 135 to respective internal address spaces 115A or 115B. As illustrated, the translation circuitry 132 may translate and/or convert an external address 137A to a memory page 112C within the first section 114A, and may translate and/or convert an external address 137B to a memory page 112M within the second section 114B.

The configuration logic 122 may cause the memory logic 120 to operate according to a second operating mode, which may comprise implementing HA memory operations within the memory substrate 160. The configuration logic 122 may, inter alia, instruct the address logic 130 to publish modifications to the external memory address space 135, and to implement redundant one-to-two translations 132, such that each external address 137 addresses two different memory pages 112. The address logic 130 may configure the translation circuitry 132 to implement a redundant addressing scheme, such that each external address 137 corresponds to a set of two different memory pages 112, including a memory page 112 within the first section 114A and a memory page 112 within the second section 114B.

The configuration logic 122 may be further adapted to direct the memory logic 120 to implement memory commands 168 in accordance with the second operating mode. The configuration logic 122 may direct the memory logic 120 to implement a memory command 168 to write data (D1) to external address 137A of the memory substrate 160 by, inter alia, causing the address logic 130 to translate and/or convert the external address 137A to two memory pages 112, the two memory pages 112 being embodied within different sections 114A and 114B of the memory substrate 160. Diagram 131D depicts one embodiment of such address translations. As illustrated, the external memory address space 135 is modified in accordance with the one-to-two HA translations implemented by the translation circuitry 132. As such, the external memory address space 135 is modified to include N/2 external addresses 137 (e.g., from 0 through N/2-1). The translation circuitry 132 may be configured to implement a redundant addressing scheme in which external addresses 137 translate to memory pages 112 to an internal address 115 within each of the internal address spaces 115A and 115B, such that each external address 137 addresses a memory page 112 within each section 114A and 114B. In the redundant addressing scheme depicted in diagram 131D, the translation circuitry 132 directly translates and/or converts external addresses 137 within the range 0 through N/2-1 to corresponding internal address sections 114A and 114B (each of which may comprise addresses ranging from 0 through N/2-1). The disclosure is not limited in this regard; the translation circuitry 132 could be configured to implement any suitable translation scheme for associating external addresses 137 with corresponding memory pages 112 within respective sections 114A and 114B.

The read/write logic 140 may be configured to perform write operation(s) on the addressed memory pages 112C and 112D, as disclosed herein. The read/write logic 140 may generate memory signals 129 configured to program the data unit (D1) to the memory pages 112C and 112D. The memory signals 129 may comprise one or more of write signal(s), program signal(s), a sequence of write pulses, a sequence of program pulses, and/or the like. The address logic 130 may be configured to couple the memory pages 112C and 112D to the read/write logic 140 and/or the memory signals 129 generated thereby, as disclosed herein.

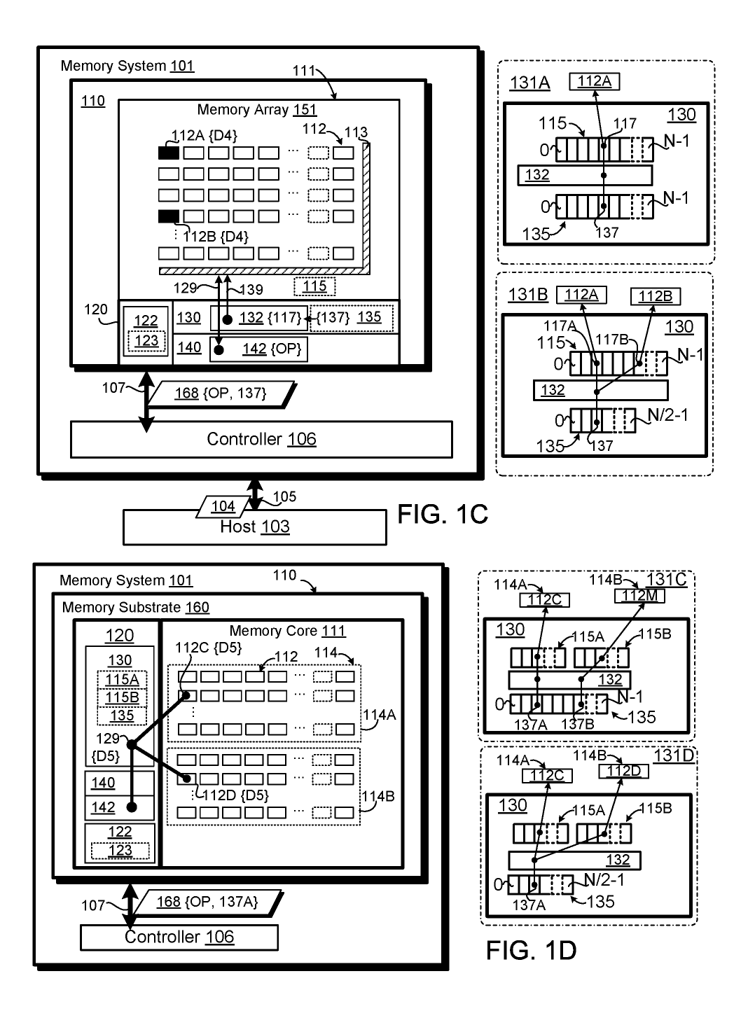

FIG. 2 is a schematic block diagram depicting further embodiments of a memory system 101 configured to implement HA memory operations. In the FIG. 2 embodiment, the memory structure 110 comprises a memory die 210. The memory die 210 may comprise a plurality of memory blocks 212. The memory blocks 212 may be formed on and/or within the memory die 210, as disclosed herein. The memory blocks 212 may be configured to store “data blocks” (e.g., in respective data areas thereof). As disclosed above, a data block refers to a particular amount and/or quantum of data (e.g., 512 bytes, 1 kb, 16 kb, and/or the like). In some embodiments, the memory blocks 212 may be configured such that an actual physical storage capacity of the memory blocks 112 exceeds the block size. The memory blocks 212 may comprise a data area and an auxiliary area, which may be used to store encoded data blocks, error detection data, error correction data, and/or the like, as disclosed herein. The memory blocks 212 may be formed on and/or within any suitable memory storage medium. The memory blocks 212 may comprise one or more non-volatile memory elements, one or more non-volatile memory cells, pages of non-volatile memory cells, and/or the like. In the FIG. 2 embodiment, the memory die 210 comprises a NAND-Flash die and the memory blocks 212 are comprised of NAND-Flash memory cells (e.g., words, pages and/or blocks of NAND-Flash memory cells).

As illustrated in FIG. 2, the memory blocks 212 may be embodied within respective planes of the memory die 210, including plane 0 and plane 1. The planes 0 and 1 may correspond to respective sections of the memory die 210 (e.g., plane 0 may not be affected by failure conditions in plane 1 (and vice versa). Accordingly, the planes 0 and 1 may correspond to different sections 114 of the memory die 210.

The memory die 210 may comprise 2N memory blocks 212. Plane 0 may comprise N memory blocks (memory blocks 212[0,0] through 212[0,N-1]) and plane 1 may comprise N memory blocks (memory blocks 212[1,0] through 212[1,N-1]). The memory die 210 may comprise memory logic 120, which may be configured to perform memory operation(s) on selected memory blocks 212. The memory logic 120 may comprise configuration logic 122, read/write logic 140 and address logic 130, as disclosed herein. The memory logic 120 may be configured to implement a memory operation in response to memory commands 268. FIG. 2 illustrates an exemplary embodiment of a memory command 268. The memory command 268 may comprise one or more fields, parameters, flags, descriptors, commands, opcodes, switches, and/or the like. By way of non-limiting example, the memory command 268 illustrated in FIG. 2 includes command code(s) 202, command data 204, and a command address 206. The command code(s) 202 may specify memory operation(s) to be performed by the memory logic 120, which may include, but are not limited to: write operations to write data block(s) to the memory system 101, read operations to read data from the memory system 101, erase, reset, and/or re-initialize operations, query operations to access configuration and/or status information, configuration operations to modify and/or set configuration parameters of the memory logic 120 (e.g., select the operating mode), and so on. The command data 204 may comprise and/or reference data to be written to the memory system 101. Alternatively, or in addition, the command data 204 may direct the memory logic 120 to transfer data to and/or from the memory system 101. The command data 204 may comprise a buffer address, interconnect address, DMA address, and/or the like, which may be used to access data being written to the memory die 210 or transfer data being read from the memory die 210. The command address 206 may comprise any suitable identifier and/or designation for data and/or a memory storage location(s) within the memory 102, which may include, but is not limited to: a block, (e.g., a block number, offset, identifier, or the like), a page (e.g., a page number, offset, identifier, or the like), a memory address, and/or the like. The command address 206 may comprise an external address 137 of an external memory address space 135, as disclosed herein. In the FIG. 2 embodiment, the command address(es) 206 may reference blocks, pages, and/or memory storage locations by use of plane identifiers (P) and block numbers (B).

The memory logic 120 may be configured to implement memory operation(s) responsive to memory commands 268. The memory logic 120 may implement a memory command 268 to write data to memory block [0,0] by, inter alia, a) addressing the memory block 212[0] within plane 0 by use of the address logic 130, and b) performing write operation(s) on the addressed memory block 212[0] by use of the read/write logic 140. The memory logic 120 may be configured to implement a memory command 268 to read data from memory block [0,0] by, inter alia: a) addressing the memory block 212[0] within plane 0 by use of the address logic 130, and b) performing read operation(s) on the addressed memory block 212[0,0] by use of the read/write logic 140, as disclosed herein.

The memory die 210 may further comprise interconnect circuitry 213A and 213B. The interconnect circuitry 213A may be configured to address selected memory blocks 212 within plane 0 (e.g., memory blocks 212[0,0] through 212[0,N-1]. The interconnect circuitry 213B may be configured to address selected memory blocks 212 within plane 1 (e.g., memory blocks 212 [1,0]. The interconnect circuitry 213A and 213B may comprise independent interconnect circuitry capable of addressing respective memory blocks 512 in planes 0 and 1 in parallel and/or concurrently (as disclosed above in conjunction with interconnect circuitry 113). In some embodiments, the memory logic 120 may be configured to perform multi-plane operations on memory blocks 212 within planes 0 and 1, as disclosed herein. A multi-plane memory operation may comprise, inter alia: using the address logic 130 to address memory blocks 212 within each plane 0 and 1 (by generating respective addressing signals 239A and 239B), and using the read/write logic 140 to perform memory operation(s) on memory blocks within planes 0 and 1 in parallel and/or concurrently (by generating memory signals 229A and 229B). The read/write logic 140 may comprise read/write circuitry 242A, which may be configured to implement read, write, and/or erase operations on memory block 212 addressed within plane 0, and read/write circuitry 242B, which may be configured to implement read, write, and/or erase operations on memory blocks 212 addressed within plane 1. The read/write circuitry 242A and 242B may implement memory operations by generating and/or sensing memory signals 229A and 229B, as disclosed herein.

The memory logic 120 may be configured to implement HA memory operations within the memory die 210. As disclosed herein, a HA memory operation may comprise reading and/or writing data blocks by use of two or more memory blocks 212 within the memory die 210. In the FIG. 2 embodiment, the memory logic 120 may be configured to implement HA memory operations to write data blocks on the memory die 210 by writing such data blocks to memory blocks 212 disposed within each of planes 0 and 1 210. Accordingly, data blocks may be protected from loss or corruption in the event of a failure of one of the memory blocks 212, and/or a failure of an entire plane 0 or 1 (or a region of plane 0 or 1). The memory logic 120 may be configured to implement high-availability write operations by, inter alia: a) writing a data block to a primary memory block 212 within one of the planes 0 or 1, and b) writing a copy of the data block to a secondary memory block 212 within the other plane 1 or 0. The memory logic 120 may be configured to implement high-availability read operations by, inter alia: a) reading the primary memory block 212 within one of the planes 0 or 1, and b) reading the secondary memory block 212 within the other plane 1 or 0, in response to a read failure, or the like.

As disclosed above, memory commands 268 may reference memory storage location(s) within the memory 102 by use of command address(es) 206. A command address 206 may correspond to a particular memory block 212 within the memory die 210 (e.g., may identify a memory block 212 by plane (P) and/or block (B), as disclosed above). The disclosure is not limited in this regard, however, and could be adapted to use any type of command address(es) 206 (e.g., internal addresses 117, external addresses 137, and/or the like, as disclosed herein). In some embodiments, the memory logic 120 may implement HA memory operations in response to a memory command 268 by, inter alia, a) addressing a primary memory block 212 corresponding to the command address 206 (the primary memory block 212 being in plane 0 or 1), and b) addressing a secondary memory block 212 from a different plane 1 or 0.

The address logic 130 may be configured to select and/or address the primary and secondary memory blocks 212 by, inter alia, translating the command address 206 in accordance with a redundant addressing scheme, as disclosed above. The address logic 130 may comprise translation circuitry 132, which may implement a redundant addressing scheme in which each command address 206 of a memory command 268 translates to a memory block 212 within plane 0 and a corresponding memory block 212 in plane 1 (and vice versa). The translation circuitry 132 may be configured to implement any suitable redundant addressing scheme, including, but not limited to: a “single-plane” redundant addressing scheme, a “multi-plane” redundant addressing scheme, and/or the like.

In a “single-plane” redundant addressing scheme, the address logic 130 may be configured to emulate single-plane memory operations. In such embodiments, the memory logic 120 may represent that the memory 102 comprises memory blocks 212 embodied within a single plane (and/or represent that the memory 102 is not capable of multi-plane operations). Memory commands 268 issued by the controller 106 may comprise “single-plane” command addresses 206 that reference memory and/or data blocks by number, offset, identifier, and/or the like, without a plane designation. The translation circuitry 132 may be configured to translate single-plane command addresses 206 to memory blocks 212 within each plane 0 and 1 based on a single-plane redundant addressing scheme. In some embodiments, the single-plane redundant addressing scheme comprises directly translating command addresses 206 to memory blocks 212 within planes 0 and 1, respectively. For example, the memory logic 120 may represent that the memory 102 comprises N memory blocks 212 in a single plane. The controller 106 may reference memory blocks by number, offset, identifier, or the like (e.g., command addresses 206 may reference blocks 0 through N-1, without a plane designation). The translation circuitry 132 may translate the “single-plane” command addresses 206 to corresponding memory blocks 212 within each plane 214 (e.g., translate block (B) to memory block 212[0,B] in plane 0 and memory block [1,B] in plane 1, where B is between 0 and N-1). In another embodiment, the single-plane redundant addressing scheme may comprise designating memory blocks 212 within one or more plane(s) 214 as “primary” memory blocks 212 and designating a corresponding set of memory blocks within the opposite plane(s) 214 as “secondary” or “redundant” memory blocks 212. The address logic 130 may, for example, designate memory blocks 212 0 through N-1 of plane 0 (or plane 1) as “primary” memory blocks 212, and designating corresponding memory blocks 212 of plane 1 (or plane 0) as “secondary” or “redundant” memory blocks 212. The translation circuitry 132 may translate command address(es) to both a primary memory block 212 in plane 0 or 1 and a secondary memory block 212 in the opposite plane 1 or 0. In another embodiment, the translation circuitry 132 may designate the even-numbered memory blocks 212 within planes 0 and 1 as “primary” memory blocks 212, and designate odd-numbered memory blocks 212 as “secondary” or “redundant” memory blocks 212. Although particular examples of single-plane redundant addressing schemes are described herein, the disclosure is not limited in this regard, and could be adapted to implement any suitable redundant addressing scheme for translating command address(es) 206 to memory blocks 212 within each plane 0 and 1, which may include, are not limited to: address offsets, address shirts, address modulo operations, any-to-any address translations, address lookup tables, and/or the like.

In a “multi-plane” redundant addressing scheme, the memory logic 120 may represent that the memory 102 comprises two (or more) planes 212 and/or is capable of implementing multi-plane operations. Accordingly, command address(es) 206 of the memory commands 268 may reference blocks within more than one plane (e.g., the command addresses 206 may comprise “multi-plane” addresses that include plane and block numbers [P,B], as illustrated in FIG. 2). The translation circuitry 132 may be configured to translate and/or convert such command addresses 206 to “primary” memory blocks 212 within either plane 0 or 1, and corresponding “secondary” memory blocks 212 within the other plane 1 or 0. In some embodiments, the multi-plane redundant addressing scheme may comprise designating a subset of N/2 memory blocks 212 within each plane 0 and 1 as “primary” or “addressable” memory blocks 212, and designating another subset of N/2 memory blocks 212 within each plane 0 and 1 as “redundant” or “non-addressable” memory blocks 212. The “primary” or “addressable” memory blocks 212 may be addressable by the controller 106 (e.g., may correspond to command address(es) 206 of memory commands 268 issued by the controller 106). The “primary” or “addressable” memory blocks 212 may, for example, include memory blocks 212 0 through (N-1)/2 within each plane 0 and 1. In this embodiment, the memory logic 120 may represent that the memory 102 comprises two planes (planes 0 and 1), and that each plane comprises N/2 memory pages 112 (ranging from memory block 212 0 through (N-1)/2). The “redundant” or “non-addressable” memory blocks 212 may include memory blocks 212 N/2 through N-1 within each plane 0 and 1. The translation circuitry 132 may be configured to associate each of the “primary” or “addressable” memory blocks 212 with a corresponding “redundant” or “non-addressable” memory block 212 (e.g., primary memory block 212[0,B] of plane 0 may correspond to a redundant memory block [1,N/2+B] within plane 1 and primary memory block 212[1,B] of plane 1 may correspond to redundant memory block [0,N/2+B] within plane 0, where B is between 0 and (N-1)/2). In another embodiment, the translation circuitry 132 may be configured to designate “primary” or “addressable” memory blocks 212 to include the even-numbered memory blocks 212 of plane 0 and the odd-numbered memory blocks 212 of plane 1, and to designate “redundant” or “non-addressable” memory blocks 212 to include the odd-numbered memory blocks 212 of plane 0 and the even-numbered memory blocks 212 of plane 1. The translation circuitry 132 may use any suitable mechanism for designating the “primary” or “addressable” memory blocks 212 and the corresponding “secondary” or “redundant” memory blocks 212, including fixed address offsets or shifts, address modulo operations, lookup tables, translation tables, any-to-any translations, and/or the like. In some embodiments, the translation circuitry 132 maintains translation metadata 232, which may define a redundant addressing scheme being implemented thereby. The translation metadata 232 may include, but is not limited to: address translation(s) being implemented by the translation circuitry 132, a lookup table, a translation table, an index, a map, and/or the like. The translation metadata 232 may be maintained by the configuration logic 122 (e.g., as part of the operating mode 123) and/or within one or more of the memory blocks 212. Alternatively, the address logic 130 may maintain the translation metadata 232 separately within one or more memory blocks 212, within one more reserve memory blocks, registers, and/or the like (not shown in FIG. 2 to avoid obscuring the details of the illustrated embodiments)

As disclosed above, when configured to implement a “multi-plane” redundant addressing scheme, the memory logic 120 may represent that the memory die 210 comprises N memory blocks 212 arranged between planes 0 and 1, each plane comprising memory blocks 212 numbered 0 through (N-1)/2. The memory logic 120 may be further configured to represent that the memory die 210 is capable of implementing multi-plane memory commands 268, as disclosed herein (and in reference to the “addressable” memory blocks 0 through (N-1)/2 of planes 0 and 1). The controller 106 may, therefore, issue memory command 268 to direct the memory logic 120 to implement multi-plane memory operations within the memory die 210. Although particular examples of multi-plane redundant addressing schemes are described herein, the disclosure is not limited in this regard, and could be adapted to implement any suitable redundant addressing scheme for translating multi-plane address information (e.g., command address(es) 206) to memory blocks 212 to corresponding sets of memory blocks 212, each set comprising a memory block 212 in each plane 0 and 1.

In the FIG. 2 embodiment, the memory logic 120 may comprise configuration logic 122 which may be adapted to configure the memory logic 120 to operate according to a selected operating mode 123, including a standard or non-HA mode, a strict HA mode, a lax HA mode, and/or the like. The selected operating mode 123 may further determine whether the memory logic 120 is configured to implement single-plane or multi-plane HA memory operations, define the redundant addressing scheme to be implemented by the address logic 130 (e.g., specify a single-plane redundant addressing scheme, a multi-plane redundant addressing scheme, or the like, as disclosed above), and so on.

The configuration logic 122 may modify the selected operating mode of the memory logic 120 responsive to commands from the controller 106 and/or host 103 (not illustrated in FIG. 2 to avoid obscuring details of the disclosed embodiments). Modifying the selected operating mode of the memory logic 120 may comprise, inter alia, a) notifying the controller of modification(s) to the memory logic 120 (e.g., changes to the addressable range of memory storage locations, external memory address space 135, and/or the like), b) configuring the address logic 130 to associate command addresses 206 with two (or more) memory blocks 212 in accordance with a particular redundant addressing scheme (e.g., single-plane, multi-plane, or the like), c) configuring the memory logic 120 to manage error and/or failure conditions in accordance with the selected operating mode (e.g., strict HA, lax HA, or the like), and so on.

As disclosed above, when configured for single-plane HA operation, the memory logic 120 may represent that the memory 102 comprises a range of memory blocks 212 within a single plane (and/or represent that the memory 102 is not capable of implementing multi-plane operations). In the FIG. 2 embodiment, the memory logic 120 may represent that the memory 102 comprises N memory blocks 212 0 through N-1 (as opposed to the full set of 2N memory blocks 212 distributed between planes 0 and 1). The controller 106 may, therefore, reference memory and/or data blocks by use of single-plane command addresses 206 (e.g., command addresses 206 that include a block number without a plane designation). The memory logic 120 may implement a command to write a data block 241 to a specified command address 206 (e.g., block (0)), by inter alia: a) addressing two different memory blocks 212 within different sections of the memory die 210 (e.g., within different planes 0 and 1), and b) storing the data block 241 on both the addressed memory blocks 212. Addressing the two different memory blocks 212 may comprise addressing a primary memory block 212 and a redundant memory block 212 in accordance with a single-plane redundant addressing scheme. In the FIG. 2 embodiment, translation circuitry 132 translates single-plane command addresses 206 to corresponding memory blocks 212 within each plane 0 and 1, such that each block (B) addresses a corresponding memory block 212 in plane 0 and 1 (e.g., memory blocks 212 [0,B] and [1,B]). The memory command 268 to write data 241 to block (0) may, therefore, comprise writing the data 241 on the memory blocks 212[0,0] and 212[1,0].

In some embodiments, the read/write logic 140 implements multi-plane write operation(s) to write the data 241 to both memory blocks 212[0,0] and 212[1,0] in parallel and/or concurrently. Accordingly, a latency of the write command 268 to write data 241 redundantly within the memory die 210 may be substantially the same as writing the data to a single memory block 212 (e.g., on a single plane 214). The memory logic 120 may implement memory commands 268 to read data 241 from block (0) by, inter alia, a) addressing memory blocks 212 [0,0] and/or [1,0] based on the single-plane redundant addressing scheme disclosed above, and b) performing read operation(s) to read the data 241 stored on one or more of the memory blocks 212 [0,0] and/or [1,0]. The memory logic 120 may implement multi-plane read operation(s) to read the data 241 from both memory blocks [0,0] and [1,0] in parallel and/or concurrently. Alternatively, the memory logic 120 may read the data 241 from one of the memory blocks 212 [0,0] or [1,0] in first read operation(s), and may perform second read operation(s) on the other memory block 212 [1,0] or [0,0] in response to detecting a failure condition pertaining to the first read operation(s). The first and/or second read operation(s) may comprise multi-plane operations, wherein other memory operations are performed in parallel and/or concurrently with the first and/or second read operation(s) on memory block 212 [0,0] or [1,0].

In some embodiments, the memory logic 120 may be configured to for multi-plane HA operation (by use of the configuration logic 122, as disclosed herein). Configuring the memory logic 120 for multi-plane HA operations may comprise configuring the address logic 130 to implement a multi-plane redundant addressing scheme, which, as disclosed above, may comprise a redundant addressing scheme in which a set of memory blocks 212 within each plane 214 corresponds to a respective memory block 212 in the other plane 214. A multi-plane redundant addressing scheme may comprise designating “primary” or “addressable” memory blocks 212 within both planes 0 and 1, such that each of the “primary” or “addressable” memory block 212 corresponds to a respective “secondary” or “redundant” memory block 212 within the opposite plane 1 or 0. When configured for multi-plane HA operation, the memory logic 120 may represent that the memory 102 comprises memory blocks 212 within different planes 0 and 1 and/or that the memory 102 is capable of implementing multi-plane memory operations. The controller 106 may, therefore, reference memory and/or data blocks by use of multi-plane command addresses 206, that include both a plane and block designation (e.g., [P,B]).

In one embodiment, the translation circuitry 132 may be configured to implement a multi-plane HA redundant addressing scheme in which memory blocks 212 0 through (N-1)/2 within each plane 214 are designated as “primary” or “addressable” memory blocks 212, with corresponding blocks N/2 through N-1 being designated as “secondary” or “non-addressable” memory blocks. The translation circuitry 132 may translate and/or convert multi-plane command addresses 206 [P,B] to memory block 212 [P,B] and [!P, B+N/2], where P is a plane designation (e.g., plane 0 or 1), !P is a designation of a plane other than P (e.g., plane 1 or 0), and B is a block number between 0 and (N-1)/2. In such embodiments, a memory command 268 to write data 243 to command address 206 [0, (N-1)/2] may comprise writing data 243 to memory block 212 [0, (N-1)/2] within plane 0 (as the primary memory block 212 for the data 243), and writing a redundant copy of the data 243 to memory block 212[1,N-1] within plane 1. Similarly, a memory command 268 to write data 245 to command address 206 [1,(N-1)/2] may comprise writing the data 245 to “primary” memory block 212[1,(N-1)/2] within plane 1 and writing a redundant copy of the data 245 to “secondary” memory block 212 [0, (N-1)/2] within plane 0. In some embodiments, the controller may issue a multi-plane memory command 268, which may be configured to direct the memory logic 120 to write data 243 and 245 in a multi-plane memory operation. The memory logic 120 may implement such a memory command 268 by performing two multi-plane operation(s), including a first multi-plane memory operation to write data 243 to memory blocks 212[0, (N-1)/2] and [1,N-1], and a second multi-plane memory operation to write data 245 to memory blocks 212[0,N-1] and [1,(N-1)/2)], as disclosed above. Implementation of the multi-plane memory command 268 according to a HA operating mode 123 may, therefore, comprise implementing two multi-plane write operations. By contrast, when configured for non-HA operation, the memory logic 120 may implement the multi-plane memory command 268 in a single multi-plane write operation (e.g., the latency for implementing multi-plane operations may differ depending on the operating mode 123 of the memory logic 120). In some embodiments, the memory logic 120 may be configured to inform the controller 106 (and/or other entity) of changes to the latency required to implement memory commands 268 based on the operating mode 123 of thereof. When configured for HA operation, the memory logic 120 may represent that the latency of multi-plane memory commands 268 is 2L, where L is a latency for one single- or multi-plane operation within the memory 102.

As disclosed above, the translation circuitry 132 may be configured to implement any suitable redundant addressing scheme. The translation circuitry 132 may, for example, be configured to designate alternative addresses within planes 0 and 1 as primary memory blocks 212, each having a corresponding secondary memory block 212 in the other plane 1 or 0. In one embodiment, the translation circuitry 132 designates even-numbered memory blocks 212[0,{0,2,4, . . . N-2}] and [1,{0,2,4, . . . N-2}] as “primary” or “addressable” memory blocks, and odd-numbered memory blocks 212 [0, {1,3,5, . . . N-1}] and [1, {1,3,5, . . . N-1}] as “secondary” or “redundant” memory blocks. The translation circuitry 132 may translate and/or convert multi-plane memory command addresses 206 [P,B] to a “primary” memory blocks 212 [P, B*2] and “secondary” memory block 212 [!P, 2B+1], where P is a plane designation (e.g., 0 or 1), !P designates a plane other than P (e.g., 1 or 0), and B is between 0 and (N-1)/2. When so configured, the memory logic 120 may implement a multi-plane memory command 268 to write data 247 and 249 to multi-plane command addresses 206 [0,1] and [1,1] by, inter alia: implementing a first multi-plane write operation to store data 247 on memory blocks 212 [0,2] and [1,3], and implementing a second multi-plane write operation to store data 249 on memory blocks [1,2] and [0,3], as disclosed herein. The memory logic 120 may implement multi-plane read operations pertaining to command addresses 206 [0,1] and/or [1,1], as disclosed herein.

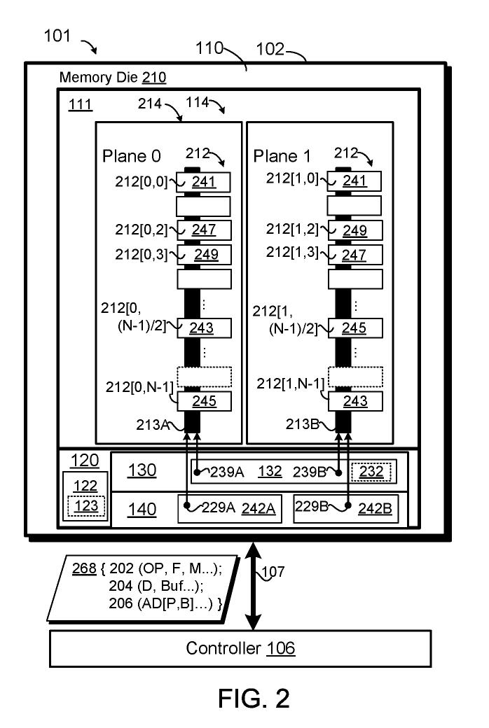

FIG. 3 is a flow diagram of one embodiment of a method for providing HA memory and/or storage services within a memory structure 110. The steps or operations of method 300, and the other methods disclosed herein, may be embodied by the memory logic 120. The steps and/or operations may be embodied as state machine logic, configuration data, firmware, computer-readable instructions stored on a non-transitory storage medium, circuit design data (e.g., a hardware description language such as VHDL), and/or the like.

Step 310 comprises receiving command at a memory 102. The commands may be issued by a controller 106 of the memory 102 (e.g., may comprise a write command 108A, a read command 108B, a memory command 168, 268, and/or the like). The commands may direct memory logic 120 of the memory 102 to perform one or more memory operations, such as operations to store data within the memory 102, read data from the memory 102, and/or the like. The commands of step 310 may specify that the memory operations are to be performed in relation to a particular data blocks, data pages, data units, and/or the like. In some embodiments, the commands comprise address information, such as external addresses 137, command addresses 206, and/or the like. The address information of the commands may pertain to a particular data storage location within the memory 102, such as a data block, data page, data unit, and/or the like (e.g., may comprise a block, page, and/or unit number, offset, identifier, or the like). Alternatively, or in addition, the address information may reference memory pages 112 and/or memory blocks 212 of the memory 102 (e.g., may comprise a memory address, a memory page or block number, a block and page designation [P,B], and/or the like). The memory logic 120 may represent that the memory 102 is capable of storing a set, range and/or extent of data blocks, pages, and/or units (e.g., 0 through N). The memory logic 120 may further represent that the memory 102 comprises different sets, ranges and/or extents in different sections (e.g., different planes, such as a set of blocks 0 through N/2 in plane 0, and a set of blocks 0 through N/2 in plane 1, as disclosed above).

In some embodiments, step 310 comprises receiving commands pertaining to the operating mode for the memory operation(s) and/or memory structure 110. Step 310 may comprise setting and/or recording an operating mode, which may include, but is not limited to: a non-HA operating mode, a standard operating mode, a HA operating mode, a lax HA operating mode, a strict HA operating mode, and/or the like. Step 310 may comprise recording the operating mode in one or more of a register, firmware, non-volatile storage, and/or the like, as disclosed herein. Step 310 may comprise determining to implement the memory operation(s) in a determined HA operating mode.

The memory logic 120 of the memory 102 may be configured to implement HA memory operations responsive to the commands of step 310. Implementing HA memory operations may comprise associating each of the commands of step 310 with two (or more) different memory pages 112 and/or blocks 212 within the memory 102. Step 320 may comprise associating a block, page, unit, or other data referenced by a command with two (or more) different memory pages 121 and/or blocks 212. Step 320 may comprise translating and/or converting address information of the commands to the two (or more) different memory pages 121 and/or blocks 212 by use of translation circuitry 132, as disclosed herein (e.g., using a redundant addressing scheme). The address translation of step 320 may comprise translating and/or converting one or more of an external address 137 (e.g., data segment address, page address, or the like) to an internal address (e.g., a physical address, a physical page address, a media address, and/or the like).

Step 320 may further comprise addressing the two (or more) different memory pages 121 and/or blocks 212 by use of address logic 130 and/or interconnect circuitry 113, 213A, and/or 213B, as disclosed herein (e.g., by generating one or more sets of addressing signals such as addressing signals 139, 239A, and/or 239B disclosed herein).

Step 330 may comprise implementing HA memory operations on the two (or more) memory pages 112 and/or blocks 212 associated with the commands of step 310. Step 330 may comprise implementing HA operations to store data blocks, pages, units, and/or the like within the memory 102. Implementing an HA operation to store a data block, page, unit, and/or other data within the memory 102 may comprise storing data of the block, page, unit, and/or the like, within two (or more) different memory pages 112 and/or blocks 212. In response to a command to store data of a particular data block within the memory 102, step 330 may comprise, inter alia: a) addressing two (or more) memory pages 112 and/or blocks 212 associated with the particular data block by use of the address logic 130, and b) performing write operation(s) to store data of the particular block on the two (or more) memory pages 112 and/or blocks 212 by use of the read/write logic 140. The write operation(s) may comprise separate write operations, concurrent operations, or the like (e.g., a single multi-plane write operation). The write operation(s) may further include replacing one or more of the memory pages 112 and/or blocks 212 responsive to a write failure pertaining to one or more of the memory pages 112 and/or blocks 212, as disclosed herein.

Step 330 may further comprise implementing an HA memory operations to read data from the memory 102. In response to a command to read data of a particular data block from the memory 102, step 330 may comprise, inter alia: a) addressing a first one of the two (or more) memory pages 112 and/or blocks 212 associated with the particular block, b) performing a first read operation on the first memory page 112 and/or 212, and c) implementing a second read operation on another one of the two (or more) memory pages 112 and/or blocks 212 associated with the particular block responsive to an error pertaining to the first read operation. Implementing a read operation may further include verifying that data of the particular block is retrievable from each of the two (or more) memory pages 112 and/or blocks 212 associated with the particular block, replacing one or more of the memory pages and/or blocks 212, and so on, as disclosed herein.

Step 330 may further include providing responses to commands received at step 310. Providing a response to a command may comprise providing an indication of whether the command was completed successfully, whether the command was partially completed, an indication that the command completed with errors, an indication that the command failed, and so on. A response may further comprise data pertaining to the command, such as data read from the memory 102 and/or the like. The manner in which commands are implemented within the memory, including translations between commands and memory pages 112 and/or blocks 212, how memory commands are implemented within the memory structure 110, how error conditions are handled, and so on, may be determined by, inter alia, configuration logic 122 of the memory 102 (e.g., the operating mode 123), as disclosed herein.

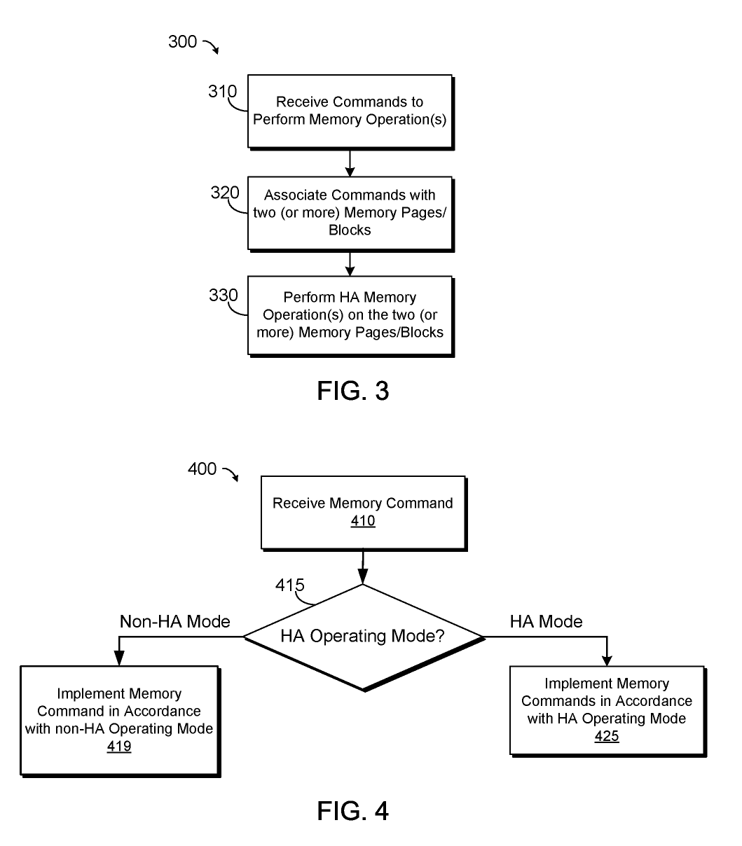

FIG. 4 is a flow diagram of another embodiment of a method for implementing memory and/or storage operations within a memory structure 110. Step 410 may comprise receiving a memory command. The memory command received at step 410 may correspond to a memory operation to perform on a memory structure 110, as disclosed herein. In some embodiments, step 410 comprises configuring the memory structure 110 to operate in designated operating mode, such as a non-HA operating mode, a standard operating mode, an HA operating mode, a lax HA operating mode, a strict HA operating mode, and/or the like. Step 410 may comprise receiving configuration command(s) directed to the memory structure 110. Step 410 may comprise setting and/or recording information pertaining to the operating mode in a register, firmware, and/or non-transitory storage of core memory logic 120, as disclosed herein.

Step 415 may comprise determining an operating mode for the memory structure 110. Step 415 may comprise determining whether to implement the memory command in a HA operating mode or a non-HA operating mode. In some embodiments, step 415 comprises determining an operating mode for the memory structure 110, as disclosed herein. The operating mode determined at step 415 may include, but is not limited to: a non-HA mode, an HA mode, a strict HA mode, a lax HA mode, and/or the like. The flow may continue at step 419 in response to determining that the operating mode for the memory structure 110 corresponds to a non-HA or standard operating mode. The flow may continue to step 425 in response to determining that the operating mode of the memory structure 110 corresponds to an HA operating mode (e.g., an HA operating mode, a strict HA operating mode, a lax HA operating mode, or the like).

Step 419 may comprise implementing the memory command in accordance with a non-HA or standard operating mode, as disclosed herein. Step 419 may comprise addressing a memory storage location and performing one or more of: writing data to the addressed memory storage location, reading data from the address memory storage location, and/or the like.

Step 425 may comprise implementing the memory commands in accordance with an HA operating mode, as disclosed herein. Step 425 may comprise associating the memory command with two memory storage locations of the memory structure. Step 425 may comprise associating the memory command with the two memory storage locations by use of a redundant addressing scheme. The two memory storage locations may be embodied within different failure domains of the memory structure 425 (e.g., different planes). Step 425 may further comprise implementing the memory command by use of the two memory storage locations. The two memory storage locations may include a first memory storage location for the memory command and a second memory storage location for the memory command. Implementing the memory command may comprise writing data to each of the two memory storage locations. Writing the data may comprise one or more of: a) a single write operation to write data to each of the two memory storage locations (a multi-plane write), b) a first write operation to write the data to the first memory storage location and a second write operation to write data to the second memory storage location, c) verifying that the data was written to each of the two memory storage locations (e.g., comparing data read from the two memory storage locations), and so on. Alternatively, or in addition, implementing the memory command at step 425 may comprise reading data from one or more of the two memory storage locations. Step 425 may comprise one or more of: a) performing a single read operation to read data from each of the two or more memory storage locations associated with the memory command, b) performing a first read operation to read data from one of the two memory storage locations, c) performing a second read operation to read data from the other one of the two memory storage locations, d) comparing data read from the two memory storage locations, and the like.

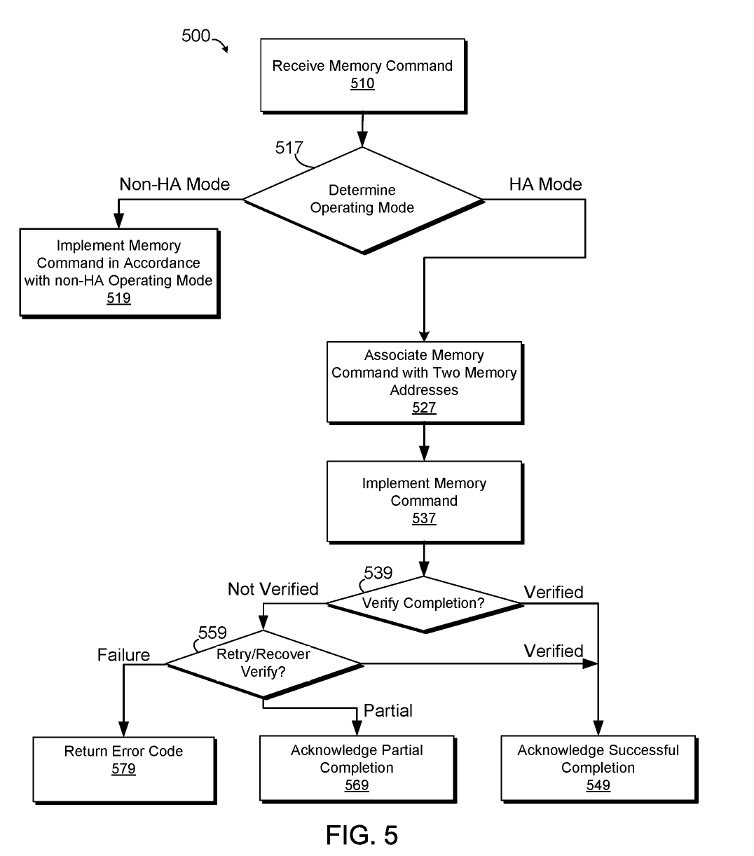

FIG. 5 is a flow diagram of another embodiment of a method for implementing memory commands within a memory structure. Step 510 comprises receiving a memory command pertaining to a memory structure 110. Step 517 comprises determining an operating mode for the memory command. The flow may continue at step 519 in response to step 517 determining a non-HA mode. Step 519 may comprise implementing the memory command in response to the determined operating mode corresponding to a non-HA operating mode. Step 519 may further comprise providing a response to the memory command which may include, but is not limited to: acknowledging completion of the memory command, acknowledging successful completion of the memory command, returning an indication that the memory command failed, or the like.

The flow may continue at step 527 in response to step 517 determining an HA mode for the memory command. Step 527 may comprise associating the memory command with two memory addresses. Step 527 may comprise implementing a selected redundant addressing scheme, as disclosed herein.

Step 537 may comprise implementing the memory command on the two or more memory addresses in accordance with the determined operating mode, as disclosed herein. Implementing a write command may comprise writing data of the memory command to each of the two memory addresses. Implementing a read command may comprise reading data from one or more of the two memory addresses. The memory command may be implemented in accordance with the operating mode determined at step 517. Implementing a write command in accordance with a lax HA operating mode may comprise verifying that the data of the memory command was written to at least one of the two memory addresses. Implementing the write command in accordance with a strict HA operating mode may comprise verifying that the data of the memory command was written to each of the two memory addresses. Implementing a read command in accordance with a lax HA operating mode may comprise reading data from one or more of the two memory addresses. Implementing the read command in accordance with a strict HA operating mode may comprise reading data from each of the two memory addresses (and/or verifying the data stored at each of the memory addresses).

Step 537 may comprise determining whether the memory command was successfully completed in accordance with the determined operating mode. In a strict HA operating mode, step 537 may comprise one or more of: verifying that data of the memory command was written to each of the two memory addresses (by, inter alia, reading data written to each of the two memory addresses) and verifying that data of the memory command was read from each of the two memory addresses. In a lax HA operating mode, step 537 may comprise one of: verifying that the data of the memory command was written to at least one of the two memory addresses, and verifying that the data of the memory command was read from at least one of the two memory addresses. In response to verifying completion of the memory command, the flow may continue at step 549. Step 549 may comprise acknowledging successful completion of the memory command. Step 549 may comprise providing additional information pertaining to completion of the memory command, such as verifying that the command was completed in accordance with an HA operating mode, such as a strict or lax HA mode (e.g., data was written to and/or read from each of two memory addresses). Step 549 may comprise providing an indication that the command completed successfully in accordance with a strict HA mode (was written to and/or read from each of the two memory addresses). Step 549 may comprise providing an indication that the command completed successfully in accordance with a lax HA mode (was written to and/or read from at least one of the two memory addresses). Step 549 may further comprise a completion status and/or warning information pertaining to the memory command. Acknowledging successful completion of the memory command in accordance with a lax HA mode may comprise indicating that the memory command was successfully implemented on only one of the two memory addresses.

Step 559 may comprise retrying and/or recovering from a failure to verify completion of the memory command. Step 559 may be implemented in response to determining that the data of the memory command was not successfully read from and/or written one or more of the memory addresses. Step 559 may be implemented in accordance with the operating mode determined at step 539. In a lax HA mode, step 559 may comprise one or more of: a) retrying the memory command to ensure that data is read from and/or written to at least one of two memory address within the memory structure 110, b) recovering from a read and/or write failure by, inter alia, replacing one or more of the memory addresses of the memory command with another memory address within the memory structure 110 (e.g., remapping the memory command to one or more different memory addresses), and/or the like. In a strict HA mode, step 559 may comprise one or more of: a) retrying the memory command to ensure that data is read from and/or written to each of two or more memory addresses within the memory structure 110, b) recovering from read and/or write failures by, inter alia, replacing one or more of the memory addresses of the memory command (e.g., remapping the memory command to one or more different memory addresses), and/or the like. Step 559 may further comprise remapping memory addresses for the memory command such that each of the two memory addresses of the memory command correspond to different failure domains of the memory structure 110 (e.g., are within different planes of the memory structure 110, or the like).

Step 559 may further comprise verifying completion of the memory command. Step 559 may comprise verifying one or more of: successful completion of the memory command, partial completion of the memory command, and failure of the memory command. Step 559 may verify completion in accordance with the determined operating mode, as disclosed herein. In a strict HA mode, step 559 may comprise verifying that data was written to and/or read from each of two memory addresses (the original memory addresses or replacement memory addresses). In a lax HA mode, step 559 may comprise verifying that data was written to and/or read from at least one of two memory addresses of the memory command. In response to verifying successful completion at step 559, the flow may continue to step 549. In response to verifying partial completion of the memory command, the flow may continue at step 569. In response to failing to verify completion of the memory command (determining that the memory command failed), the flow may continue at step 579.

Step 559 may comprise verifying partial completion of the memory command in accordance with the operating mode determined at step 517. Verifying partial completion may comprise verifying that the data of the memory command was written to and/or read from at least one memory address of the memory structure 110. In some embodiments, a strict HA operating mode may require that a failure code be returned when data cannot be verified in each of two (or more) memory addresses of the memory structure 110. In such embodiments, verifying partial completion of the memory command at step 559 (to only one memory address) may result in returning a failure at step 579. In other embodiments, the strict HA operating mode may allow partial completion of the memory commands (and/or may stipulate reporting status information). In such embodiments, verifying partial completion of the memory command may comprise verifying that the data of the memory command was written to and/or read from at least one memory address, and continuing the flow at step 569.

Step 569 may comprise acknowledging partial completion of the memory command. Acknowledging partial completion may comprise acknowledging successful completion at least a portion of the memory command (e.g., acknowledging that data of the memory command was written to and/or read from at least one memory address of the memory structure 110). The acknowledgment of step 569 may be implemented in accordance with the operating mode determined at step 517. In a lax HA operating mode, acknowledging partial completion at step 569 may comprise returning an indication of successful completion (as in step 549). In other embodiments, acknowledging partial completion in accordance with the lax HA operating mode may comprise acknowledging successful completion of the memory command and, inter alia, providing status information indicating that the memory command was not completed in a HA mode (e.g., data of the command is not available on each of two memory addresses of the memory structure 110). Acknowledging partial completion in accordance with a strict HA operating mode may comprise a) returning an error (per step 579 below), b) returning a warning, c) returning a completion indicator with status information indicating partial completion, and/or the like.

Step 579 may comprise returning an indication that the memory command failed. Step 579 may be implemented in accordance with the operating mode determined at step 517. In a lax HA mode, step 579 may comprise returning an error indicating that the data of the memory command was not written to and/or read from any of two memory addresses associated with the memory command (and/or that replacement memory addresses were not available). In a HA mode, step 579 may comprise returning an error indicating that data of the memory command was not written to and/or read from each of two memory addresses associated with the memory command (and/or that replacement memory addresses were not available). Step 579 may comprise returning an indication that the data was successfully written to and/or read from at least one of the memory addresses.

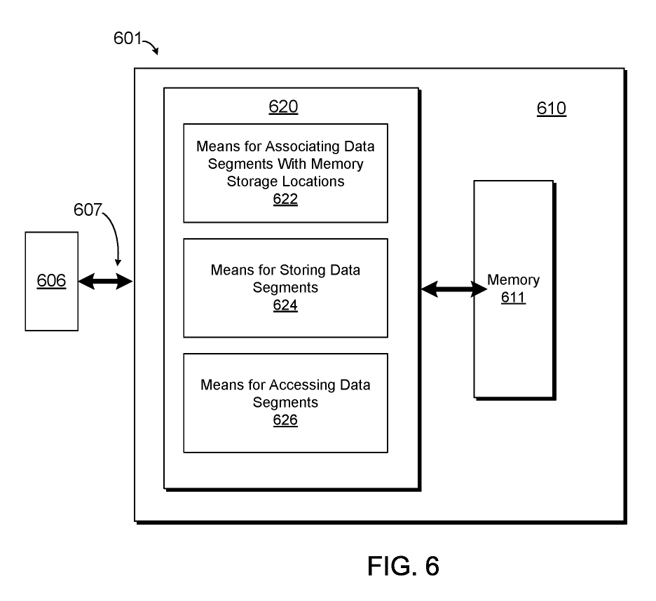

FIG. 6 is a schematic block diagram depicting embodiments of a memory system 601 configured to provide highly-available memory storage services. The memory system 601 may comprise memory structure means 610 comprising memory means 611. The memory structure means 610 may be embodied as a memory structure 110, as disclosed herein. The memory structure 610 may comprise, but is not limited to: a chip, a package, a die, a substrate, a semiconductor substrate, a semiconductor, a semiconductor wafer, a Flash memory die, a NAND-Flash die, a NOR-Flash die, combinations and/or portions thereof, and/or the like. The memory means 611 may comprise a plurality of memory storage locations (not shown to avoid obscuring the details of the illustrated embodiments). The memory means 611 may be embodied within a memory region of the memory structure means 610. The memory storage locations may be embodied as non-volatile memory cells, memory pages 112, and/or the like. The memory means 611 may comprise an array of memory cells including, but not limited to: a two-dimensional array of memory cells, a three-dimensional array of memory cells, and/or the like.

The memory system may comprise means for associating data segments with memory storage locations 622, such that each data segment is associated with two (or more) memory storage locations. In some embodiments, each data segment is associated with a respective primary memory storage location and a respective secondary memory storage location. The means for associating data segments with memory storage locations 622 may implement a redundant addressing scheme, such that each external address 137 of an external memory address space 135 of the memory system 601 (e.g., each data segment address) corresponds to at least to two internal addresses 117 of memory storage locations within the memory means 611 (e.g., two different physical memory addresses). The means for associating data segments with memory storage locations 622 may operate according to a selected operating mode and/or may implement a particular redundant addressing scheme, as disclosed herein. The means for associating data segments with memory storage locations 622 may associate each data segment with storage locations within different respective failure domains (e.g., different sections 114, such as different respective memory planes). The means for associating data segments with memory storage locations 622 may include, but are not limited to: interconnect logic 113, memory logic 120, configuration logic 122, address logic 130, translation circuitry 132, combinations and/or portions thereof, and/or the like, as disclosed herein. The means for associating data segments with respective memory storage locations 622 may be embodied as hardware components and/or circuitry corresponding to the disclosed interconnect logic 113, memory logic 120, configuration logic 122, address logic 130, translation circuitry 132, combinations and/or portions thereof, and/or the like, as disclosed herein.

The memory system 601 may further comprise means for storing data segments 624. The means for storing data segments 624 may comprise means for storing respective data segments on each of the two or more memory storage locations associated therewith, including a primary storage location and a secondary storage location. The means for storing data segments 624 may include, but are not limited to: interconnect logic 113, address logic 130, read/write logic 140, read/write circuitry 142, combinations and/or portions thereof, and/or the like, as disclosed herein. The means for storing data segments 624 may be embodied as hardware components and/or circuitry corresponding the disclosed interconnect logic 113, address logic 130, read/write logic 140, and read/write circuitry 142, which may include, but is not limited to: write circuitry, read circuitry, erase circuitry, read/write circuitry, program circuitry, drive circuitry, bias circuitry, sense circuitry, sense amplifier circuitry, current sense circuitry, voltage sense circuitry, verification circuitry, error correction and/or detection circuitry, combinations and/or portions thereof, and/or the like.

The memory system 601 may further comprise means for accessing data segments 626, as disclosed herein. The means for accessing data segments 626 may comprise means for performing a first read operation on the primary memory storage location associated with the data segment, and performing a second read operation on the secondary memory storage location associated with the data segment in response to a failure of the first read operation. The means for accessing data segments 626 may include, but are not limited to: interconnect logic 113, address logic 130, read/write logic 140, read/write circuitry 142, combinations and/or portions thereof, and/or the like, as disclosed herein. The means for accessing data segments 626 may be embodied as hardware components and/or circuitry corresponding the disclosed interconnect logic 113, address logic 130, read/write logic 140, and read/write circuitry 142, which may include, but is not limited to: read circuitry, write circuitry, erase circuitry, read/write circuitry, program circuitry, drive circuitry, bias circuitry, sense circuitry, sense amplifier circuitry, current sense circuitry, voltage sense circuitry, verification circuitry, error correction and/or detection circuitry, combinations and/or portions thereof, and/or the like.

In some embodiments, the means for associating data segments with memory storage locations 622, the means for storing data segments 624, and the means for accessing data segments 626 may be embodied as memory logic means 620. The memory logic means 620 may comprise memory logic 120, as disclosed herein, which may be embodied within a periphery region of the memory structure means 610 (and may comprise configuration logic 122, address logic 130, translation circuitry 132, read/write logic 140, read/write circuitry 142, combinations and/or portions thereof, and/or the like.

In some embodiments, the memory logic means 620 may comprise and/or be communicatively coupled to memory control means 606. The memory logic means 620 may expose an external memory address space 135 to the memory control means 606 (e.g., expose a range of external addresses 137 to the memory control means 606, such as a range data segment addresses). As disclosed above, each external address 137 may correspond to two internal addresses 115 within the memory 611 (e.g., two physical memory addresses). The memory control means 606 may issue commands to the memory system 601 via interconnect means 607 (e.g., memory core interconnect 107). The memory control means 606 may issue commands to configure the memory system 101 (e.g., determine an operating mode 123 for the memory system 601, as disclosed herein). The memory control means 606 may be further configured to issue commands to read and/or write data segments (by use of respective external, data segment addresses). The memory logic means 620 may implement memory commands issued thereto and provide responses to the memory control means 606, as disclosed herein. The responses may comprise acknowledging completion of the commands, acknowledging partial completion of the memory commands, providing error information pertaining to the commands, indicating failure of the memory commands, and so on, as disclosed herein. The memory control means 606 may be embodied hardware and/or circuitry components which may include, but are not limited to: state machines, data registers, control registers, volatile RAM, SRAM, control circuitry, firmware, combinations and/or portions thereof, and/or the like.

While this disclosure has been described with reference to embodiments for exemplary fields and applications, it should be understood that the embodiments are not limited thereto. Other embodiments and modifications thereto are possible, and are within the spirit and scope of this disclosure. For example, and without limiting the generality of this paragraph, embodiments are not limited to the software, hardware, firmware, and/or entities illustrated in the figures and/or described herein. Further, embodiments (whether or not explicitly described herein) have significant utility to fields and applications beyond the examples described herein.

Embodiments have been described herein with the aid of functional building blocks illustrating the implementation of specified functions and relationships thereof. The boundaries of these functional building blocks have been arbitrarily defined herein for the convenience of the description. Alternate boundaries can be defined as long as the specified functions and relationships (or equivalents thereof) are appropriately performed. Also, alternative embodiments may perform functional blocks, steps, operations, methods, etc. using orderings different than those described herein.

References herein to “one embodiment,” “an embodiment,” “an example embodiment,” or similar phrases, indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it would be within the knowledge of persons skilled in the relevant art(s) to incorporate such feature, structure, or characteristic into other embodiments whether or not explicitly mentioned or described herein.

The breadth and scope of the disclosure should not be limited by any of the above-described embodiments, but should be defined only in accordance with the following claims and their equivalents.

We claim:

1. A memory device, comprising:
a memory die comprising a plurality of physical memory pages; and
memory logic configured to store a data page redundantly within the memory die in response to a command to store the data page within the memory die, the memory logic configured to write the data page to two or more physical memory pages of the memory die, including a first physical memory page and a second physical memory page in response to the command.

2. The memory device of claim 1, wherein the physical memory pages comprise memory cells embodied within a memory region of the memory die, and wherein the memory logic is embodied within the memory die.

3. The memory device of claim 1, further comprising address logic configured to associate the data page with each of the two or more physical memory pages of the memory die.

4. The memory device of claim 1, wherein the memory die comprises N memory pages, and wherein the memory logic is configured to represent that the memory die comprises a range of N/2 page addresses, the memory logic further comprising:
address logic configured to translate data page addresses to physical memory pages of the memory die, such that each data page address translates to two different physical memory pages of the memory die.

5. The memory device of claim 1, wherein the memory die comprises a first plane and a second plane, the memory device further comprising:
address logic configured to associate data page addresses with physical memory pages of the memory die, each data page address being associated with at least one physical memory page within the first plane and at least one physical memory page within the second plane.

6. The memory device of claim 1, wherein the command comprises a single-plane write command, and wherein the memory logic is configured to write the data page to the memory die in a multi-plane write operation, the multi-plane write operation configured to program the data page to both of the first physical memory page within a first plane of the memory die and to the second physical memory page within a second plane of the memory die.

7. The memory device of claim 1, wherein the memory logic is configured to operate in a specified one of a strict redundancy mode and a non-strict redundancy mode, and wherein, in response to storing the data page in the first physical memory page and failing to store the data page in the second physical memory page, the memory logic is configured to provide one of:
an indication that the command failed when the memory logic is configured to operate in the strict mode, and
an indication that the command was completed when the memory logic is configured to operate in the non-strict mode.

8. A memory system, comprising:
a memory structure comprising a memory region and a periphery region;
a plurality of memory pages, each memory page embodied within one of a first plane of the memory region and a second plane of the memory region; and
memory circuitry embodied within the periphery region of the memory structure, the memory circuitry comprising,
address circuitry configured to associate data pages with memory pages of the memory structure, such that each data page stored within the memory structure is associated with at least two memory pages, the at least two memory pages including a memory page embodied within the first plane of the memory region and a memory page embodied within the second plane of the memory region, and
write circuitry configured to store data pages such that the data pages are replicated within the memory structure, wherein to store a data page within the memory structure, the write circuitry is configured to write the data page to each of the at least two memory pages associated with the data page by the address circuitry, including a memory page embodied within the first plane of the memory region and a memory page embodied within the second plane of the memory region.

9. The memory system of claim 8, wherein the memory circuitry further comprises read circuitry configured to read data pages stored within the memory structure, wherein to read a data page, the read circuitry is configured to read one or more of the at least two memory pages associated with the data page by the address circuitry.

10. The memory system of claim 8, wherein the read circuitry is configured to read data from a first one of the at least two memory pages in a first read operation, and to read data from a second one of the at least two memory pages in a second read operation in response to an error pertaining to the first read operation.

11. The memory system of claim 10, wherein the write circuitry is configured to write data to a replacement memory page in response to the error pertaining to the first read operation.

12. A method, comprising:
receiving a command to store a data unit within a memory die, the memory die comprising a plurality of memory blocks, each memory block configured to store a respective data unit within respective non-volatile memory cells;
implementing a high-availability write operation in response to the command, the high-availability write operation to write the data unit to at least two memory blocks of the memory structure, and comprising,
addressing at least two memory blocks of the memory structure, including a first memory block and a second memory block, and
using write circuitry of the memory structure to perform one or more write operations to write the data unit to each of the at least two memory blocks of the memory structure, including the first memory block and the second memory block.

13. The method of claim 12, wherein the memory structure comprises two planes, and wherein implementing the high-availability write operation comprises addressing memory blocks within each of the planes of the memory structure such that the data unit is written to a memory block within each of the planes of the memory structure.

14. The method of claim 12, wherein implementing the high-availability write operation comprises performing a multi-plane write operation configured to write the data unit to each of the first memory block and the second memory block.

15. The method of claim 12, wherein implementing the high-availability write operation further comprises translating a data unit address to physical addresses of each of the at least two memory blocks of the memory structure, the at least two memory blocks including a memory block embodied within a first plane of the memory structure and a memory block embodied within a second plane of the memory structure.

16. The method of claim 12, further comprising implementing a high-availability read operation to read a data unit from a specified data address, the high-availability read operation comprising:
converting the specified data address to two or more memory block addresses, the memory block addresses including a primary memory block address and a secondary memory block address,
performing a first read operation on the primary memory block address, and
performing a second read operation on the secondary memory block address responsive to an error pertaining to the first read operation.

17. The method of claim 16, wherein implementing the high-availability read operation further comprises:
replacing one of the primary memory block and the secondary memory block with a reserve memory block of the memory structure; and
using the write circuitry of the memory structure to write data corresponding to the specified data address to the reserve memory block.

18. The method of claim 12, further comprising servicing a request to read a specified data unit address, by:
translating the specified data unit address to two memory block addresses, the two memory block addresses corresponding to memory blocks within different respective planes of the memory structure, and
performing a multi-plane read operation directed to both of the memory block addresses.

19. The method of claim 12, further comprising determining a redundancy mode for the command, the redundancy mode comprising one of a lax mode and a strict mode, wherein implementing the high-availability write operation further comprises one of:
acknowledging completion of the command in response to the data unit being successfully stored within at least one of the two memory blocks of the memory structure and the determined redundancy mode being the lax mode; and
returning an indication that the command failed in response to a failure to store the data unit within each of the two memory blocks of the memory structure and the determined redundancy mode being the strict mode.

20. A memory system, comprising:
means for associating data segments with memory storage locations within a memory die, each data segment being associated with a respective primary memory storage location within the memory die and a respective secondary memory storage location within the memory die;
means for storing the data segments within the memory die, each data segment being written to each of the primary memory storage location associated with the data segment and the secondary memory storage location associated with the data segment; and
means for accessing data segments stored within the memory die, wherein accessing a data segment stored within the memory die comprises:
performing a first read operation on the primary memory storage location associated with the data segment, and
performing a second read operation on the secondary memory storage location associated with the data segment in response to a failure of the first read operation,
wherein the means for associating, the means for storing, and the means for accessing are embodied on the memory die.
